(19) United States
(12) Patent Application Publication
(10) Pub. No.: US 2023/0131912 A1
(43) Pub. Date: Apr. 27, 2023

(54) DISPLAY PANEL AND METHOD FOR MANUFACTURING THE SAME

(71) Applicant: Samsung Display Co., Ltd., Yongin-Si, Gyeonggi-do (KR)

(72) Inventors: HEESUNG YANG, Hwaseong-si (KR); Joon-Hwa Bae, Suwon-si (KR); Sukyeong Shin, Hwaseong-si (KR); Woojin Cho, Yongin-si (KR)

(21) Appl. No.: 17/865,501

(22) Filed: Jul. 15, 2022

(30) Foreign Application Priority Data
Oct. 22, 2021 (KR) 10-2021-0141908

(51) Int. Cl. H01L 51/52; H01L 27/32; H01L 51/56

(52) U.S. Cl. CPC H01L 51/5253; H01L 27/3246; H01L 27/322; H01L 51/56

(57) ABSTRACT

A display panel includes an emission area and a non-emission area. A light emitting element includes a first electrode, an emission layer on the first electrode, and a second electrode on the emission layer. A pixel defining layer includes a first opening defined therein and exposing the first electrode. A first encapsulation layer is on the second electrode to overlap the light emitting element. The first encapsulation layer includes a first inorganic layer on the second electrode and a second inorganic layer on the first inorganic layer. A top surface of the second electrode overlaps the first opening and includes at least one first stepped portion. A bottom surface of the second inorganic layer directly contacts a top surface of the first inorganic layer. At least one of the top surface of the first inorganic layer or a top surface of the second inorganic layer is a flat surface.

### CROSS-REFERENCE TO RELATED APPLICATIONS

This application claims priority under 35 U.S.C, § 119 to Korean Patent Application No. 10-2021-0141908, filed on Oct. 22, 2021 in the Korean Intellectual Property Office, the disclosure of which is incorporated by reference in its entirety herein.

### 1. TECIINICAL FIELD

The present inventive concept herein relates to a display panel and a method for manufacturing the same.

### 2. DISCUSSION OF RELATED ART

Various types of display devices are used to provide images to a user. A self-luminous display device that uses an organic electroluminescent material or a quantum dot light emitting material is in development.

The self-luminous display device includes a light emitting element. Since the light emitting element is vulnerable to environmental contaminants, such as oxygen and moisture, various technologies for sealing the light emitting element have been developed. For example, an encapsulation layer that blocks a penetration path of air and moisture by disposing the encapsulation layer on the light emitting element is in development.

### SUMMARY

An embodiment of the present inventive concept provides a display panel including an encapsulation layer having increased moisture permeability resistance and increased optical properties and a method fin' manufacturing the same.

According to an embodiment of the present inventive concept, a display panel comprising an emission area and a non-emission area adjacent to the emission area. The display panel includes a light emitting element comprising a first electrode, an emission layer disposed on the first electrode, and a second electrode disposed on the emission layer. A pixel defining layer includes a first opening defined therein. The first opening exposes at least a portion of the first electrode. A first encapsulation layer is disposed on the second electrode to overlap the light emitting element. The first encapsulation layer includes a first inorganic layer disposed on the second electrode. A second inorganic layer is disposed on the first inorganic layer. A top surface of the second electrode overlapping the first opening comprises at least one first stepped portion. A bottom surface of the second inorganic layer directly contacts a top surface of the first inorganic layer. At least one of the top surface of the first inorganic layer or a top surface of the second inorganic layer is a flat surface.

In an embodiment, the first encapsulation layer may have a thickness in a range of about 1.0 μm in to about 5.0 μm.

In an embodiment, the first inorganic layer may cover the first stepped portion, and the top surface of the first inorganic layer may be a flat surface on the emission area.

In an embodiment, a first height from a bottom surface of the first electrode to the top surface of the first inorganic layer on the emission area may be the same as a second height from a bottom surface of the pixel defining layer to the top surface of the first inorganic layer on the non-emission area.

In an embodiment, the top surface of the first inorganic layer may include a second stepped portion corresponding to the first stepped portion.

In an embodiment, the second inorganic layer may cover the second stepped portion, and the top surface of the second inorganic layer may be a flat surface on the emission area.

In an embodiment, an arithmetic mean roughness of the top surface of the first inorganic layer may be greater than an arithmetic mean roughness of the top surface of the second inorganic layer.

In an embodiment, the first encapsulation layer may further include a third inorganic layer disposed on the second inorganic layer.

In an embodiment, the display panel may further include: a division partition wall disposed on the first encapsulation layer and including a second opening defined therein. The second opening corresponds to the first opening. A light control pattern is disposed inside the second opening. A second encapsulation layer is disposed on the division partition wall to overlap the light control pattern. A color filter is disposed on the second encapsulation layer to overlap the light control pattern.

In an embodiment, the second encapsulation layer may have a thickness in a range of about 1.0 μm to about 5.0 μm.

In an embodiment, the second encapsulation layer may include: a first encapsulation inorganic layer disposed on the division partition wall; and a second encapsulation inorganic layer disposed on the first encapsulation inorganic layer. A bottom surface of the second encapsulation inorganic layer may directly contact a top surface of the first encapsulation inorganic layer.

According to an embodiment of the present inventive concept, a display panel includes a light emitting element including a first electrode, an emission layer disposed on the first electrode, and a second electrode disposed on the emission layer. A pixel defining layer includes a first opening defined therein. The first opening exposes at least a portion of the first electrode. A first encapsulation layer is disposed on the second electrode to overlap the light emitting element. The first encapsulation layer includes a first inorganic layer disposed on the second electrode; and a second inorganic layer disposed on the first inorganic layer. The first encapsulation layer has a thickness in a range of about 1.0 μm to about 5.0 μm.

In an embodiment, at least one of a top surface of the first inorganic layer or a top surface of the second inorganic layer may be a flat surface.

In an embodiment, the first encapsulation layer may further include an organic layer disposed between the first inorganic layer and the second inorganic layer, and the organic layer may have a thickness in a range of about 0.1 μm to about 2.0 μm .

According to an embodiment of the present inventive concept, a method for manufacturing a display panel includes preparing a light emitting element. A first encapsulation layer is formed on the light emitting element. The forming of the first encapsulation layer includes: forming a first inorganic layer on the light emitting element; and forming a second. inorganic layer on the first inorganic layer. The forming of the first encapsulation layer includes planarizing through a polishing process at least one of a top surface of the first inorganic layer or a top surface of the second inorganic layer.

In an embodiment, the polishing process may include a chemical mechanical polishing process.

In an embodiment, the forming of the first inorganic layer may include: forming a first preliminary inorganic layer on the light emitting element; and polishing a top surface of the first preliminary inorganic layer.

In an embodiment, a thickness of the first preliminary inorganic layer that is removed in the polishing of the top surface of the first preliminary inorganic layer may be less than or equal to about 3.0 μm.

In an embodiment, the forming of the second inorganic layer may include: forming a second preliminary inorganic layer on the first inorganic layer; and polishing a top surface of the second preliminary inorganic layer.

In an embodiment, the forming of the first encapsulation layer may further include forming a third inorganic layer on the second inorganic layer after the forming of the second inorganic layer.

### BRIEF DESCRIPTION OF THE FIGURES

The accompanying drawings are included to provide a further understanding of the present inventive concept, and are incorporated in and constitute a part of this specification. The drawings illustrate non-limiting embodiments of the present inventive concept and, together with the description, serve to explain principles of the present inventive concept. In the drawings:

FIG. 1A is a perspective view of a display panel according to an embodiment of the present inventive concept;

FIG. 1B is a cross-sectional view of the display panel according to an embodiment of the present inventive concept;

FIG. 1C is a plan view of the display panel according to an embodiment of the present inventive concept;

FIGS. 2A to 2C are cross-sectional views of the display panel taken along line of FIG. 1C according to embodiments of the present inventive concept;

FIG. 3 is a flowchart illustrating a method for manufacturing a display panel according to an embodiment of the present inventive concept;

FIG. 4 is a flowchart illustrating a process of forming a first inorganic layer according to an embodiment of the present inventive concept;

FIGS. 5A, 5B, 5D and 5F are cross-sectional views illustrating a process of manufacturing the display panel according to embodiments of the present inventive concept;

FIG. 5C is an enlarged cross-sectional views of area AA1 of FIG. 5B according to an embodiment of the present inventive concept;

FIG. 5E is an enlarged cross-sectional views of area AA2 of FIG. 5D according to an embodiment of the present inventive concept;

FIG. 6 is a flowchart illustrating a process of forming a second inorganic layer according to an embodiment of the present inventive concept;

FIGS. 7A, 7B, 7D and 7F are cross-sectional views illustrating a process of manufacturing the display panel according to embodiments of the present inventive concept;

FIG. 7C is an enlarged cross-sectional views of area AA3 of FIG. 7B according to an embodiment of the present inventive concept;

FIG. 7E is an enlarged cross-sectional views of area AA4 of FIG. 7D according to an embodiment of the present inventive concept;

### DETAILED DESCRIPTION OF ENIBODIMENTS

Hereinafter, embodiments of the present inventive concept will be described with reference to the accompanying drawings.

In this specification, it will also be understood that when one component (or region, layer, portion, etc.) is referred to as being ‘on’, ‘connected to’, or ‘coupled to’ another component, it can be directly connected/coupled on/to the one component, or an intervening third component may also be present.

Like reference numerals refer to like elements throughout. Also, in the figures, the thickness, ratio, and dimensions of components are exaggerated for clarity of illustration. The term “and/or” includes any and all combinations of one or more of the associated listed items.

It will be understood that although the terms such as ‘first’ and ‘second’ are used herein to describe various elements, these elements should not be limited by these terms. The terms are only used to distinguish one component from other components. For example, a first element referred to as a first element in an embodiment can be referred to as a second element in a different embodiment without departing from the scope of the present inventive concept. The terms of a singular form may include plural forms unless referred to the contrary.

Also, “under”, “below”, “above”, “upper”, and the like are used for explaining relation association of components illustrated in the drawings. The terms may be a relative concept and described based on directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof.

In this specification, “being directly disposed” may mean that there is no layer, film, area, plate, or the like between a portion of the layer, the film, the area, the plate, or the like and the other portion. For example, “directly disposed” may mean being disposed without using an additional member such and an adhesion member between two layers or two members.

Unless otherwise defined, all terms (including technical and scientific terms) used herein have the same meaning as commonly understood by a person of ordinary skill in the art to which the present inventive concept belongs. In addition, terms such as those defined in commonly used dictionaries should be interpreted as having a meaning consistent with the meaning in the context of the related technology, and unless explicitly defined here, the terms should not be interpreted as too ideal or too formal sense.

Hereinafter, embodiments of the present inventive concept will be described with reference to the accompanying drawings.

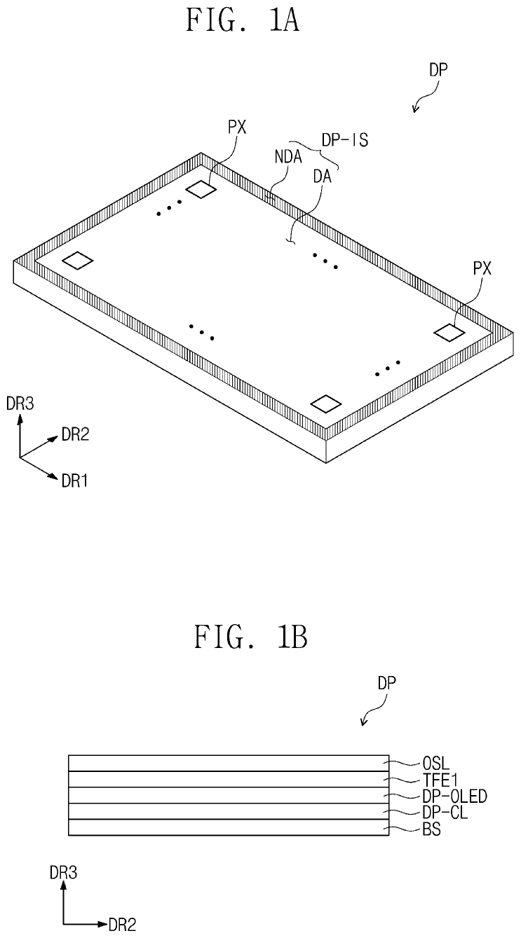

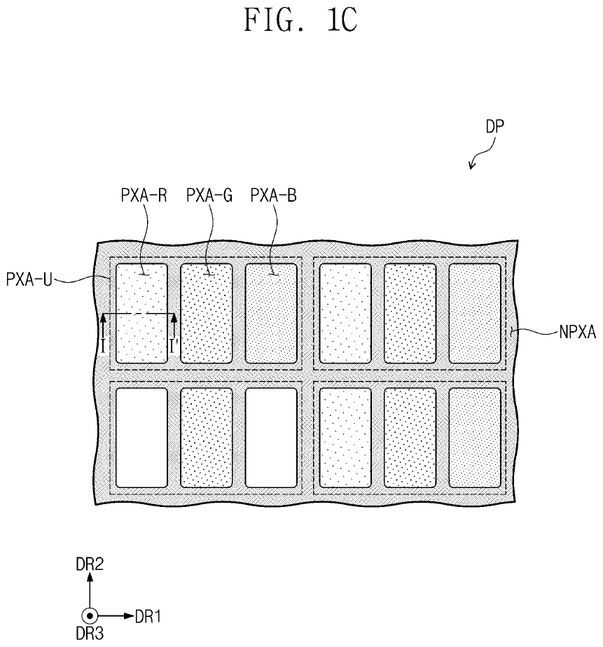

FIG. 1A is a perspective view of a display panel DP according to an embodiment of the present inventive concept. FIG. 1B is a cross-sectional view of the display panel DP according to an embodiment of the present inventive concept. FIG. 1C is a plan view of the display panel DP according to an embodiment of the present inventive concept.

The display panel DP illustrated in embodiments shown in FIGS. 1A and 1B is an emission type display panel and may be either an inorganic light emitting display panel or an organic light emitting display panel. However, embodiments of the present inventive concept are not necessarily limited thereto.

As illustrated in FIG. 1A., the display panel DP may display an image through a display surface DF-IS. The display surface DP-IS is parallel to a surface defined by a first direction DIU and a second direction DR2.

A top surface of a member disposed at the uppermost side of the display panel DP may be defined as the display surface DP-IS. The top surface of a light control member OSL illustrated in an embodiment of FIG. 1B may be defined as the display surface DP-IS of an embodiment of FIG. 1A. In an embodiment, the display surface DP-IS is parallel to a surface defined by a first direction DRI and a second direction DR2. A normal direction of the display surface DP-IS, such as a thickness direction of the display panel DP is indicated as a third direction DR3. A front surface (e.g., a top surface) and a rear surface (e.g., a bottom surface) of each of layers or units, which will be described below, are distinguished by the third direction DR3. However, the first to third directions illustrated in this embodiment may be merely examples. For example, in some embodiments, the first to third directions DR1 to DR3 may not necessarily be perpendicular to each other and may cross each other at various different angles.

The display panel DP may include a display area DA and a non-display area NDA. A pixel PX is disposed on the display area DA and is not disposed on the non-display area NDA. The non-display area NDA is defined along an edge of the display surface DP-IS The non-display area NDA may surround the display area DA. For example, in an embodiment, the non-display area NDA may completely surround the display area DA (e.g., in the first and second directions DR1, DR2). However, embodiments of the present inventive concept are not necessarily limited thereto and the non-display area NDA may not surround the display area DA on at least one side in some embodiments. For example, in an embodiment, the non-display area NDA may be omitted or may be disposed at only one side of the display area DA.

Although the display panel DP having a planar display surface DP-IS is illustrated in an embodiment of the present inventive concept, embodiments of the present inventive concept are not necessarily limited thereto. The display panel DP may include a curved display surface or a solid display surface. The solid display surface may include a plurality of display areas that indicate different directions.

Also, the display panel DP may be a rollable display panel, a foldable display panel, or a slidable display panel. The display panel DP may have a flexible property and may be folded or rolled after being installed in the display device.

As illustrated in FIG. 1B, the display panel DP includes a base substrate BS, a circuit element layer DP-CL disposed on the base substrate BS, a display element layer DP-OLED, a first encapsulation layer TFE1, and a light control member OSL. The base substrate BS may include a glass substrate, a plastic substrate, or an organic/inorganic composite substrate. The circuit element layer DP-CL, includes a driving circuit or a signal line of the pixel PX. The display element layer DP-OLED includes a light emitting element disposed in each of the pixels PX. The first encapsulation layer TFE1 includes at least one inorganic layer that encapsulates the light emitting element. The light control member OSL converts optical properties of source light generated in the light emitting element.

Referring to an embodiment of FIG. 1C, the display panel DP has a plurality of emission areas and a non-emission area NPXA adjacent to the plurality of emission areas. The plurality of emission areas illustrated in an embodiment of FIG. 1C are illustrated as being arranged in a plane defined in a first direction DR1 and a second direction DR2.

In an embodiment, the plurality of emission areas may include a first emission area PXA-R, a second emission area PXA-G, and a third emission area PXA-B. A peripheral. area NPXA may set a boundary between the first to third pixel areas PXA-R, PXA-G, and PXA-B to prevent colors from being mixed with each other between the first to third pixel areas PXA-R, PXA-G, and PXA-B.

The plurality of emission areas may include the first emission area PXA-R providing a first color light (e.g., red light), the second emission area PXA-G providing a second color light (e.g., green light), and the third light emission area PXA-B providing a third color light (e.g., blue light). However, the main three colors may be changed in various other combinations and are not particularly limited thereto. The emission area PXA to be described later will be described as the first emission area providing the red light.

Since cross-sectional structures of the first emission area PXA-R, the second emission area PXA-G, and the third emission area PXA-B are substantially the same, the first emission area PXA-R will be described as an example. Differences between the first emission area PXA-R, the second emission area PXA-G, and the third emission area PXA-B are specified below, and configurations other than the specified configuration may be considered as being the same.

The first emission area PXA-R, the second emission area PXA-G, and the third emission area PXA-B may be disposed to be spaced apart from each other in the first direction DRI. In an embodiment, the first emission areas PXA-R, the second emission areas PXA-G, and the third emission areas PXA-B may be alternately and repeatedly disposed in the first direction DR1.

One first emission area PXA-R, one second emission area PXA-G, and one third emission area PXA-B constitute one unit area PXA-U. The plurality of unit areas PXA-U may be arranged in the first direction DRI and the second direction DR2. However, embodiments of the present inventive concept are not limited thereto. For example, in an embodiment, one first emission area PXA-R, two second emission areas PXA-G, and one third emission area PXA-B may constitute one unit area PXA-U.

Surface areas of the first emission area PXA-R, the second emission area PXA-G, and the third emission area PXA-B may be the same as or different from each other. However, embodiments of the present inventive concept are riot necessarily limited thereto. Although an embodiment of FIG. 1C illustrates an arrangement relationship of the first to third pixel areas PXA-R, PXA-G, and PXA-B, the arrangement relationship is not particularly limited thereto.

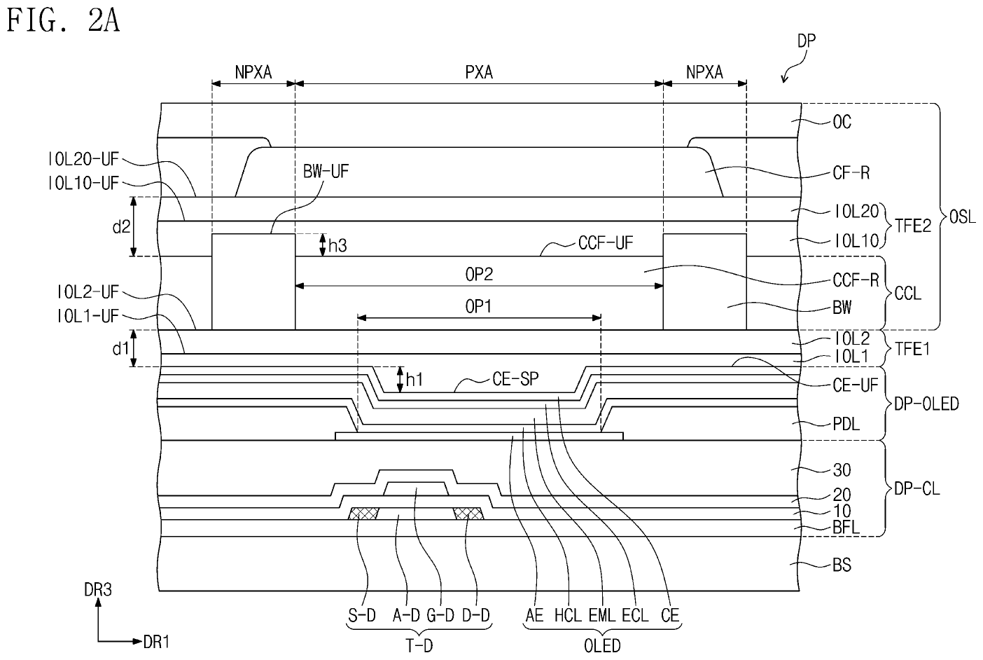

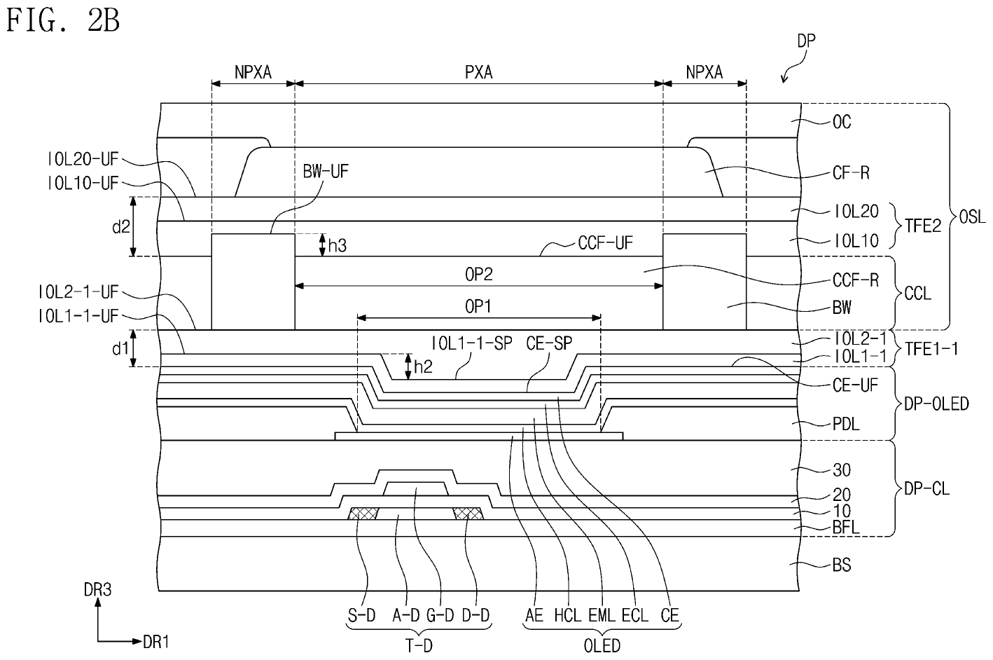

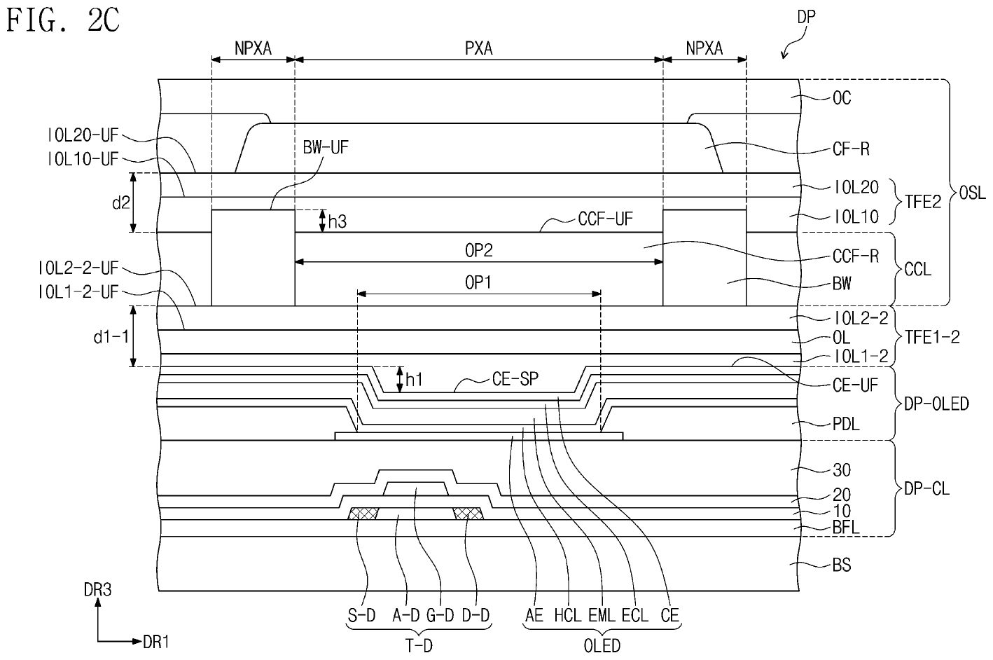

Hereinafter, the display panel DP according to embodiments will be described in detail with reference to FIGS. 2A to 2C.

FIG. 2A is a cross-sectional view of the display panel according to an embodiment of the present inventive concept. FIG. 2A illustrates a cross-sectional view of a display device, taken along line I-I′ of FIG. 1C,

The display area DA (see FIG. 1A) includes an emission area PXA and a non-emission area NPXA adjacent to the emission area PXA. The non-emission area NPXA sets a boundary between the plurality of emission areas PXA to prevent colors from being mixed between the emission areas PXA. In an embodiment, the emission area PXA is defined to correspond to a second opening OP2 to be described later. The non-emission area NPXA is defined as an area on which a division partition wall BW is disposed.

Referring to FIG. 2A, a cross section of the pixel PX corresponding to a driving transistor T-D and the light emitting element OLED is illustrated as an example. The display layer DP may include a plurality of insulating layers, a semiconductor pattern, a conductive pattern, a signal line, and the like. In an embodiment, the insulating layer, the semiconductor layer, and the conductive layer may be formed through processes such as coating, deposition, and the like. Thereafter, the insulating layer, the semiconductor layer, and the conductive layer may be selectively patterned through photolithography and etching processes. The semiconductor pattern, the conductive pattern, and the signal line, which are provided in the circuit element layer DP-CL and the display element layer DP-OLED, may be formed in the above-described manner.

In an embodiment, the circuit element layer DP-CL may include a buffer layer BFL, a first insulating layer 10, a second insulating layer 20, and a third insulating layer 30, For example, each of the first insulating layer 10 and the second insulating layer 20 may be an inorganic layer, and the third insulating layer 30 may be an organic layer.

FIG. 2A illustrates an example of an arrangement relationship of an active A-D, a source S-D, a drain D-D, and a gate G-D. The active A-D, the source S-D, the drain D-D may be areas that are divided according to a doping concentration or conductivity of the semiconductor pattern.

The display element layer DP-OLED includes a light emitting diode OLED. The light emitting element OLED may generate source light. The light emitting element OLED may include a first electrode AE, a second electrode CE, and an emission layer EML disposed between the first electrode AE and the second electrode CE (e.g., in the third direction DR3). In an embodiment, the display element layer DP-OLED may include an organic light emitting diode as the light emitting diode. The display element layer DP-OLED includes a pixel defining layer PDL. For example, the pixel defining layer PDL may be an organic layer. The pixel defining layer PDL may include a typical black coloring agent. For example, the pixel defining layer PDL may include a black dye and a black pigment, which are mixed with a base resin. In an embodiment, the black component may include carbon black or may include a metal such as chromium or an oxide thereof.

A first electrode AE is disposed on the third insulating layer 30 (e.g., directly thereon in the third direction DR3). The first electrode AE is directly or indirectly connected to the driving transistor T-D. In an embodiment, a connection structure may be disposed between the first electrode AE and the driving transistor T-D. A first opening OP1 is defined in the pixel. defining layer PDL. The opening OP1 exposes at least a portion of the first electrode AE. For example, as shown in an embodiment of FIG. 2A, the opening OP1 may expose a central portion (e.g., in the first direction DR1) of the first electrode AE.

In an embodiment, a hole control layer HCL, an emission layer EML and an electron control layer ECL may be commonly disposed on the emission area PXA and the non-emission area NPXA. The hole control layer HCL, the emission layer EML, and the electron control layer ECL may be commonly disposed on the plurality of emission areas. The emission layer EML of the plurality of emission areas may have an integral shape. The emission layer of the first emission area PXA-R, the emission layer of the second emission area PXA-G, and the emission layer of the third emission area PXA-B may have an integral shape, and each of the emission layers may generate source light having the same color regardless of the area.

The hole control layer HCL may include a hole transport layer and may further include a hole injection layer. In an embodiment, the emission layer EML may generate blue light. In an embodiment, the blue light may have a wavelength in a range of about 410 nm to about 480 nm. For example, an emission spectrum of the blue light may have a peak within a wavelength in a range of about 440 nm to about 460 nm. The electron control layer ECL may include an electron transport layer and may further include an electron injection layer.

FIG. 2A illustrates an example in which the hole control layer HCL, the emission layer EML, and the electron control layer ECL of the light emitting element OLED within the first opening OP1 defined in the pixel defining layer PDL are provided as common layers on the emission area PXA and the non-emission area NPXA. However, embodiments of the present inventive concept are not necessarily limited thereto. For example, in an embodiment, the hole control layer HCL, the emission layer EML, and the electron control layer ECL may be arranged to be patterned inside the first opening OP1 defined in the pixel defining layer PDL. Alternatively, the emission layer EML of the light emitting element OLED may be patterned in the first opening OP1, and the hole control layer HCL and the electron control layer ECL may be provided as the common layers on the emission area PXA and the non-emission area NPXA.

The second electrode CE is disposed on the electron control layer ECL (e.g., directly thereon in the third direction DR3). The second electrode CE may be commonly disposed on the plurality of emission areas. The plurality of emission areas may include the second electrode CE having an integral shape.

A top surface CE-UF of the second electrode CE may include at least one first stepped portion CE-SP. The first stepped portion CE-SP may overlap the emission area PXA and may not overlap the non-emission area NPXA. The first stepped portion CE-SP may have a groove shape that is concavely recessed by a predetermined height difference. The first stepped portion CE-SP may be provided by the first opening OP1 defined in the pixel defining layer PDL. For example, the first stepped portion. CE-SP may overlap the first opening OP1 (e.g., in the third direction DR3). As a portion of the light emitting element OLED is disposed in the first opening OP1, the first stepped portion CE-SP may be positioned on the top surface CE-UF of the second electrode CE.

The first stepped portion CE-SP of the second electrode CE may have a first height difference h1. The first height difference h1 may be defined as a height difference between the top surface GE-UF of the second electrode CE at a portion overlapping the pixel defining layer PDL (e.g., an uppermost portion of the pixel defining layer PDL) and the first stepped portion CE-SP disposed to overlap the first opening OP1, The first stepped portion CE-SP may be the lowermost portion of the top surface. CE-UF of the second electrode CE overlapping the first opening (e.g., in the third direction DR3). The first stepped portion CE-SP may have the same first height difference h1 for each of the respective emission areas PXA. For example, all of the first stepped portions CE-SP of the second electrode CE overlapping the first emission area PXA-R (see FIG. 1C), the second emission area PXA-G (see FIG. 1C), and the third emission area PXA-B (see FIG. 1C) may have the first height difference h1. However, embodiments of the present disclosure are not necessarily limited thereto, and the height differences of the first stepped portions CE-SP may be different for the respective emission areas PXA. For example, in an embodiment, the first stepped portions CE-SP of the second electrode CE overlapping the first emission areas PXA-R (see FIG. 1C), the second emission areas PSA-G (see FIG. 1C), and the third emission areas PXA-B (see FIG. 1C) may have height differences different from each other.

A first encapsulation layer TFE1 may be disposed on the light emitting element OLED, and the first encapsulation layer TFE1 may be disposed on the second electrode CE. In an embodiment, the first encapsulation layer TFE1 may be directly disposed on the second electrode CE (e.g., in the third direction DR3). The first encapsulation layer TFE1 may include at least one inorganic layer. The first encapsulation layer TFE1 may be a thin film encapsulation layer. The first encapsulation layer TFE1 may protect the light emitting element OLED from moisture and oxygen. The first encapsulation layer TFE1 may cover the light emitting element OLED. The light emitting element OLED may be sealed by the first encapsulation layer TFE1 In an embodiment, the display panel DP may further include a refractive index control layer above the first encapsulation layer TFE1 to increase emission efficiency.

In an embodiment, the first encapsulation layer TFE1 may include a first inorganic layer IOL1 and a second inorganic layer IOL2 disposed on the first inorganic layer IOL1. The second inorganic layer IOL2 may be directly disposed on the first inorganic layer IOL1. For example, a bottom surface of the second inorganic layer IOL2 may be in direct contact with a top surface of the first inorganic layer IOL1.

The first inorganic layer IOL1 may be disposed on the second electrode CE. The first inorganic layer IOL1 may cover the first stepped portion CE-SP of the second electrode CE. For example, the height difference of the first stepped portion CE-SP of the second electrode CE may be removed and be planarized by the first inorganic layer IOL1. As the first inorganic layer IOL1 covers the first stepped portion CE-SP of the second electrode CE, at least one stepped portion corresponding to the first stepped portion CE-SP may be defined on the bottom surface of the first inorganic layer IOL1.

In an embodiment, at least one of the first inorganic layer IOL1 or the second inorganic layer IOL2 may be planarized through a polishing process. For example, at least one of a top surface IOL1-UF of the first inorganic layer IOL1 or a top surface IOL2-UF of the second inorganic layer IOL2 may be planarized through a polishing process. In an embodiment in which the first and second inorganic layers IOL1 and IOL2 contain inorganic materials, each of the first and second inorganic layers IOL1 and IOL2 may have a barrier property against moisture and oxygen based on being thin and dense, but may have a disadvantage in that a pinhole is defined by a rough surface and particles, and thus, the barrier property may be deteriorated. According to an embodiment, as at least one of the top surface IOL1-UF of the first inorganic layer IOL1 or the top surface IOL2-UF of the second inorganic layer IOL2 is planarized through the polishing process, the surface roughness may be reduced, and surface particles may be removed to suppress the formation of the pinhole. Thus, the barrier property of the first encapsulation layer TFE1 may be further increased. In addition, since the stepped portion provided on the display element layer DP-OLED may be removed without introducing a separate planarization layer, efficiency of the manufacture of the display device may be increased. In this specification, the “surface roughness” may mean an arithmetic mean roughness (Ra).

In an embodiment, the top surface IOL1-UF of the first inorganic layer IOL1 disposed in at least the display area DA (see FIG. 1A) may be a flat surface. The top surfaces IOL1-UF of the first inorganic layer IOL1 disposed on the emission area PXA and the non-emission area NPXA of the display area DA (see FIG. 1A) may be a flat surface. For example, a height (e.g., a first height) from the bottom surface of the first electrode AE to the top surface IOL1-UF of the first inorganic layer IOL1 (e.g., in the third direction DR3) on the emission area PXA may be the same as a height (e.g., a second height) front the bottom surface of the pixel defining layer PDL to the top surface IOL-1-UF of the first inorganic layer IOL1 on the non-emission area NPXA. Thus, the top surface IOL1-UF of the first inorganic layer IOL1 overlapping the first stepped portion CE-SP on the emission area PXA may be flat

Each of the first inorganic layer IOL1 and the second inorganic layer LOL2 may be provided through various methods. For example, in an embodiment, each of the first inorganic layer IOL1 and the second inorganic layer IOL2 may be provided through a method such as chemical vapor deposition (CVD), plasma enhanced chemical vapor deposition (PECVD), sputter, atomic layer deposition (ALD), or thermal evaporation. However, embodiment of the present inventive concept are not necessarily limited thereto.

Each of the first inorganic layer IOL1 and the second inorganic layer IOL2 may include metal oxide and/or metal nitride. For example, each of the first inorganic layer IOL1 and the second inorganic layer IOL2 may include at least one compound selected from silicon oxide, silicon nitride, silicon oxynitride, aluminum oxide, aluminum nitride, aluminum oxynitride, titanium oxide, titanium nitride, tantalum oxide, tantalum nitride, hafnium oxide, hafnium nitride, zirconium oxide, zirconium nitride, cerium oxide, cerium nitride, in oxide, tin nitride, and magnesium oxide. In an embodiment, each of the first inorganic layer IOL1 and the second inorganic layer IOL2 may include at least one of silicon oxide, silicon nitride, or silicon oxynitride. However, embodiment of the present inventive concept are not necessarily limited thereto.

In an embodiment, a thickness d1 of the first encapsulation layer TFE1 (e.g., length in the third direction DR3) may be in a range of about 1.0 μm to about 5.0 μm. In an embodiment in which the thickness d1 of the first encapsulation layer TFE1 is less than about 1.0 μm, a film quality may be deteriorated, and the barrier property against moisture and oxygen may be deteriorated, and also, it may be difficult to planarize the stepped portion provided on the display element layer DP-OLED because the thin film is thin. In addition, in an embodiment in which the thickness d1 of the first encapsulation layer TFE1 is greater than about 5.0 μm, mechanical properties due to external stress may be deteriorated, and damage such as cracks may occur in the thin film. In an embodiment in which the thickness d1 of the first encapsulation layer TFE1 satisfies the above-described range, the barrier property may be increased due to a relatively dense film quality during the deposition process, and thus, the mechanical properties due to the external stress may be increased to increase durability and reliability of the display device.

In encapsulation technology of the display device according to the related art, an organic-inorganic multilayered thin film encapsulation technology in which the inorganic layer and the organic layer are sequentially stacked on the light emitting element in the form of a thin film has been used. In the comparative embodiment of the organic-inorganic multilayered thin film structure, water permeability may be effectively reduced, but light transmittance in a visible light region may be reduced due to the introduction of the thick organic layer to deteriorate the emission efficiency of the light emitting element. In addition, in the process of forming the organic layer on the inorganic layer through an inkjet process, there may be a limitation in that ink aggregation occurs, or an embossing phenomenon in which the surface of the organic layer is wavy is expressed. The light may not properly pass at a point at which the aggregation and embossing phenomena occur to deteriorate visibility of the display device.

In an embodiment of the present inventive concept, since the top surface of at least one inorganic layer included in the first encapsulation layer TFE1 is planarized through the polishing process, a separate organic layer may not be required for the surface planarization. For example, at least one of the top surface IOL1-UF of the first inorganic layer IOL1 or the top surface IOL2-UF of the second inorganic layer IOL2 of the first encapsulation layer TFE1 may be planarized through the polishing process. Thus, at least one of the first inorganic layer IOL1 or the second inorganic layer IOL2 may serve to planarize by removing the stepped portion provided by the first opening OP1 from the first inorganic layer IOL1 and/or the second inorganic layer IOL2, and thus, a separate organic layer may not be required for planarization to realize simplification and shortening of a tact time. In addition, since it is possible to prevent the agglomeration or embossing phenomenon from occurring in the inkjet process for forming the organic layer, the visibility of the display device may be increased. In addition, since it is possible to prevent the light transmittance from being deteriorated due to the thick organic layer, the emission efficiency of the light emitting element may be increased.

Referring again to an embodiment of FIG. 2A, a light control member OSL may be disposed on the first encapsulation layer TFE1. The light control member OSL may include a light control layer CCL, a second encapsulation layer TFE2, a color filter CF-R, and a protective layer OC. The light control layer CCL may include a division partition wall BW and a light control pattern CCF-R.

The division partition wall BW may include a base resin having high light transmittance and an additive. In general, the base resin may include various resin compositions that are called binders. The additive may include a coupling agent and/or a photoinitiator. The additive may further include a dispersant.

In an embodiment, the division partition wall BW may include a black coloring agent to block light. The division partition wall BW may include a Hack dye or a black pigment mixed with a base resin. In an embodiment, the black component may include carbon black or may include a metal such as chromium or an oxide thereof.

The division partition wall BW may include a second opening OP2 corresponding to the first opening OP1. In the plan view (e.g., in a plane defined in the first and second directions DR1, DR2), the second opening OP2 may overlap the first opening OP1 and have a surface area greater than that of the first opening OP1.

A light control pattern CCF-R may be disposed inside the second opening OP2. The light control pattern. CCF-R may change optical properties of the source light. The light control pattern CCF-R of each of the first emission area and the second emission area may be a color conversion pattern capable of converting the color of the source light. For example, in an embodiment, the color conversion pattern of the first emission area may convert a blue light source into red light, and the color conversion pattern of the second emission area may convert the blue light source into green light. The color conversion pattern of the third emission area may be a transmissive pattern. The color conversion pattern of the third emission area may scatter the received blue light including scattering particles and then emit the blue light. The light control pattern CCF-R may increase luminance of the emitted light compared to the incident light.

In an embodiment, the color conversion layer may include a base resin and quantum dots mixed (dispersed) in the base resin. In this embodiment, the color conversion pattern may include quantum dots, and the color conversion pattern may be defined as a quantum dot pattern, and color conversion patterns of the first pixel region and the second pixel region include quantum dots different from each other. The base resin may be a medium in which the quantum dots are dispersed. In general, the base resin may include various resin compositions that are called binders. However, embodiments of the present inventive concept are not necessarily limited thereto. In this specification, a medium capable of dispersing the quantum dots may be called the base resin regardless of its name, additional other functions, constituent materials, and the like. In an embodiment, the base resin may be a polymer resin. For example, the base resin may include an acrylic-based resin, a urethane.-based resin, and a silicon-based resin, and an epoxy-based resin. The base resin may be a transparent resin.

In an embodiment, the light control pattern CCF-R may be formed by the inkjet process. A liquid composition may be provided in the second opening OP2. The composition may be polymerized by a thermal curing process or a light curing process and may be reduced in volume after curing.

The color conversion pattern may further include scattering particles mixed with the base resin like the above-described transmission pattern. In an embodiment, the scattering particles may be titanium oxide (TiO₂) or silica-based nanoparticles. However, embodiments of the present inventive concept are not necessarily limited thereto.

The quantum dots may be particles that convert a wavelength of incident light. Each of the quantum dots may be a material having a crystal structure having a size of several nanometers. The quantum dot may be composed of hundreds to thousands of atoms to provide a quantum confinement effect in which an energy band gap increases due to the small size. When light having a wavelength with energy greater than that of the band gap is incident into the quantum dots, the quantum dots may absorb the light and thus be in an excited state to emit light having a specific wavelength, thereby becoming a ground state. The emitted light has a value corresponding to a band gap. When the quantum dots are adjusted in size and composition, light emitting characteristics due to the quantum confinement effect may be adjusted.

In an embodiment, the quantum dots may be selected from Group II-VI compounds, Group III-VI compounds, Group I-III-VI compounds, Group III-V compounds, Group III-II-V compounds, Group IV-VI compounds, Group IV elements, Group IV compounds, and a combination thereof.

The Group II-VI compounds may be selected from binary element compounds selected from the group consisting of CdSe, CdTe, CdS, ZnS, ZnSe, ZnTe, ZnO, HgS, HgSe, HgTe, MgSe, MgS, and a combination thereof, ternary element compounds selected from the group consisting of CdSeS, CdSeTe, Cd.STe, ZnSeS, ZnSeTe, ZnSTe, HgSeS, HgSeTe, HgSTe, CdZnS, CdaSe, CdZnTe, CdHgSe, CdHgTe, HgZnS, HgZnSe, HanTe, MgZnSe, MgZnS, and a combination thereof, and quaternary element compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a combination thereof.

Group compounds may include binary compounds such as In₂S₃ and In₂Se₃; ternary compounds such as InGaS₃ and InGaSe₃; or any combination thereof.

The group compounds may be selected from ternary compounds selected from the group consisting of AgInS, AgInS₂, CuInS, CuInS₂, AgGaS₂, CuGaS₂ CuGaO₂, AgGaO₂, AgAlO₂ and mixtures thereof or quaternary compounds such as AgInGaS₂ and CuInGaS₂.

The Group III-V compounds may be selected from binary element compounds selected from the group consisting of GaN, GaP, GaAs, GaSb, AlN, AlP, AlAs, AlSb, InN, InP, InAs, InSb, and a combination thereof, ternary element compounds selected from the group consisting of GaNP, GaNAs, GaNSb, GaPAs, GaPSb, AlNP, AlNAs, AlNSb, AlPAs, AlPSb, InGaP, InAlP, InNP, INAs, InNSb, InPAs, InPSb, and a combination thereof, and quaternary element compounds selected form the group consisting of GaAlNA.s, GaAlNSb, GaAlPAs, GaAlPSb, GaInNP, GaInNAs, GaInNSb, GaInPAs, GaInPSb, InAlNSb, InAlNAs, InAlNSb, InAlPAs, InAlPSb, and a combination thereof. The Group III-V compounds may further include the Group II metal. For example, InZnP or the like may be selected as the group III-II-V compounds.

The Group IV-VI compounds may be selected from binary element compounds selected from the group consisting of SnS, SnSe, SnTe, PbS, PbSe, PbTe, and a combination thereof, ternary element compounds selected from the group consisting of SnSeS, SnSeTe, SnSTe, PbSeS, PbSeTe, PbSTe, SnPbS, SnPbSe, SnPbTe, and a combination thereof and quaternary element compounds selected form the group consisting of SnPbSSe, SnPbSeTe, SnPbSTe, and a combination thereof. The Group IV elements may be selected from the group consisting of Si, Ge, and a combination thereof. The Group IV compounds may be binary element compounds selected from the group consisting of SiC, SiGe, and a combination thereof.

Here, the binary element compounds, the ternary element compounds, and the quaternary element compounds may exist in particles at a uniform concentration or exist in particles in a state in which concentration distribution is partitioned into partially different states. Alternatively, the quantum dot may have a core/shell structure in which one quantum dot surrounds the other quantum dot. A core/shell structure may have a concentration gradient in which an element existing in the shell has a concentration that gradually decreases toward the core.

In some embodiments, the quantum dot may have a core-shell structure, which includes a core including the above-described nano crystal and a shell surrounding the core. The shell of the quantum dot may serve as a protection layer that prevents the core from being chemically changed to maintain the semiconductor characteristics and/or may serve as a charging layer for imparting electrophoretic characteristics to the quantum dot. The shell may be a single layer or a multi-layer. For example, the shell of the quantum dot may include oxide of a metal or nonmetal, a semiconductor compound, or a combination thereof.

For example, the oxide of the metal or nonmetal may include binary element compounds of SiO₂, Al₂O₃, TiO₂, ZnO, MnO, Mn₂O₃, Mn₃O₄, CuO, FeO, Fe₂O₃, Fe₃O₄, CoO, Co₃O₄, NIO, and the like or ternary element compounds MgAl₂O₄, CoFe₂O₄, NiFe₂O₄, CoMn₂O₄, and the like. However, embodiments of the present inventive concept are not necessarily limited thereto.

Alternatively, the semiconductor compounds may include CdS, CdSe, CdTe, ZnS, ZnSe, ZnTe, InSeS, ZnTeS, GaAs, GaP, GaSb, HgS, HgSe, HgTe, InAs, InP, InGaP, AlAs, AlP, AlSb, and the like. However, embodiments of the present inventive concept are not limited thereto.

In an embodiment, the quantum dot may have a full width of half maximum (FWHM) of an emission wavelength spectrum of about 45 nm or less, preferably about 40 nm or less, more preferably about 30 nm or less. In this range, color purity and color reproducibility may be increased. Also, light emitted through the quantum dot may be emitted in all directions to increase an optical viewing angle.

Also, the quantum dot has any shape that is generally used in the art and is not specifically limited in shape. For example, the quantum dot may have a spherical shape, a pyramidal shape, a multi-arm shape, a cubic nanoparticle shape, a nanotube shape, a nanowire shape, a nanofiber shape, a nanoplate particle shape, or the like. The quantum dot may adjust a color of emitted light according to a size thereof. Thus, the quantum dot may emit light having various colors such as a blue color, a red color, and a green color.

The top surface of the light control layer CCL may be defined as a top surface BW-UF of the division partition wall BW and a top surface CCF-UF of the light control pattern CCF-R. A third height difference h3 may be formed on the top surface of the control layer CCL. The third height difference h3 may be defined as a height difference (e.g., length in the third direction DR3) between the top surface BW-UF of the division partition wall BW and the top surface CCF-UF of the light control pattern CCF-R. In an embodiment, the third height difference h3 may be in a range of about 2 μm to about 3 μm. In this specification, the top surface CCF-UF of the light control pattern CCF-R may be referred to as a third stepped portion.

A second encapsulation layer TFE2 may be disposed on the light control layer CCL. The second encapsulation layer TFE2 may include at least one encapsulation inorganic layer. The second encapsulation layer TFE2 may include a first inorganic encapsulation layer IOL10 and a second inorganic encapsulation layer IOL20 disposed on the first inorganic encapsulation layer IOL10 (e.g., disposed directly thereon in the third direction DR3). The first encapsulation inorganic layer IOL10 and the second encapsulation inorganic layer IOL20 may protect the light control pattern CCF-R from external moisture and may remove the stepped portions defined by the top surface BW-UF of the division partition wall BW and the top surface CCF-UF of the light control pattern CCF-R to provide a flat base surface on a member to be disposed above the light control layer CCL.

The first encapsulation inorganic layer IOL10 may be disposed on the light control layer CCL and cover the third stepped portion CCF-UF disposed on the top surface of the light control layer CCL. For example, a height difference of the third stepped portion CCF-UF may be removed and planarized by the first encapsulation inorganic layer IOL10. As the first encapsulation inorganic layer IOU10 covers the third stepped portion CCF-UF of the light control layer CCL, at least one stepped portion corresponding to the third stepped portion CCF-UF may be defined on a bottom surface of the first encapsulation inorganic layer IOL10. The second inorganic encapsulation layer IOL20 may be directly disposed on the first inorganic encapsulation layer IOL10. For example, the bottom surface of the second encapsulation inorganic layer IOL20 may be in direct contact with the top surface IOL10-UF of the first encapsulation inorganic layer IOL10.

In an embodiment, at least one of the first inorganic encapsulation layer IOL10 or the second inorganic encapsulation layer IOL20 may be planarized through the polishing process. For example, at least one of the top surface IOL10-UF of the first encapsulation inorganic layer IOL10 or the top surface IOL20-UF of the second encapsulation inorganic layer IOL20 may be planarized through the polishing process. As illustrated in FIG. 2A, when the top surface IOL10-UF of the first encapsulation inorganic layer IOL10 has a flat surface, the top surface IOL10-UF of the first encapsulation inorganic layer IOL10 may be planarized through the polishing process. In this embodiment, the top surface of the second encapsulation inorganic layer IOL20 which is disposed on the planarized first encapsulation inorganic layer IOL10 may also have a flat surface.

In an embodiment, the top surface IOL10-UF of the first encapsulation inorganic layer IOL10 disposed in at least the display area DA (see FIG. 1A) may be a flat surface. The top surface IOL10-UF of the first encapsulation inorganic layer IOL10 disposed on the emission area PXA and the non-emission area NPXA of the display area DA (see FIG. 1) may be a flat surface. For example, a height (e.g., length in the third direction DR3) from the bottom surface of the light control pattern CCF-R to the top surface IOL10-UF of the first encapsulation inorganic layer IOL10 on the emission area PXA may be the same as that from the bottom surface of the division partition wall BW to the top surface IOL10-UF of the first encapsulation inorganic layer IOL10 on the non-emission area NPXA. Thus, the top surface IOL10-UF of the first encapsulation inorganic layer IOL10 overlapping the third stepped portion CCF-UF on the emission area PXA may be flat.

In an embodiment, each of the first encapsulation inorganic layer IOL10 and the second encapsulation inorganic layer IOL20 may include metal oxide and/or metal nitride. For example, each of the first encapsulation inorganic layer IOL10 and the second encapsulation inorganic layer IOL20 may include at least one compound selected from silicon oxide, silicon nitride, silicon oxynitride, aluminum oxide, aluminum nitride, aluminum oxynitride, titanium oxide, titanium nitride, tantalum oxide, tantalum nitride, hafnium oxide, hafnium nitride, zirconium oxide, zirconium nitride, cerium oxide, cerium nitride, tin oxide, tin nitride, and magnesium oxide. In an embodiment, each of the first encapsulation inorganic layer IOL10 and the second encapsulation inorganic layer IOL20 may include at least one compound selected from silicon oxide, silicon nitride, and silicon oxynitride.

A thickness d2 of the second encapsulation layer TFE2 may be in a range of about 1.0 μm to about 5.0 μm. In an embodiment in which the thickness d2 of the second encapsulation layer TFE2 is less than about 1.0 μm, the film quality may be deteriorated, and the barrier property against moisture and oxygen may be deteriorated, and also, it may be difficult to planarize the stepped portion provided on the top surface of the light control layer CCL because the thin film is thin. In an embodiment in which the thickness d2 of the second encapsulation layer TFE2 is greater than about 5,0 μm, mechanical properties due to external stress may be deteriorated, and damage such as cracks may occur in the thin film. In an embodiment in which the thickness d2 of the second encapsulation layer TFE2 satisfies the above-described range, the barrier property may be increased due to a relatively dense film quality during the deposition process, and thus, the mechanical properties due to the external stress may be increased to increase durability and reliability of the display device.

The color filter CF-R is disposed on the second encapsulation layer TFE2 (e.g., directly thereon in the third direction DR3). The color filter CF-R transmits light in a specific wavelength range and blocks light in a range except for the corresponding wavelength range. The color filter CF-R of the first emission area may transmit red light. The color filter of the second emission area may transmit green light. The color filter of the third emission area may transmit blue light.

In an embodiment, the color filter CF-R includes a base resin and a dye and/or pigment dispersed in the base resin. The base resin may be a medium in which the dye and/or pigment are dispersed. In general, the base resin may include various resin compositions that are called binders.

The color filter CF-R disposed on the flat surface by removing the height difference through the second encapsulation layer TFE2 may have a uniform thickness within the emission area PXA. The red light generated by the color conversion pattern CCF-R may be provided to the outside with uniform luminance within the emission area PXA.

A protective layer OC is disposed on the color filter CF-R (e.g., disposed directly thereon in the third direction DR3). The protective layer OC may be an organic layer that protects the color filters CF-R. The protective layer OC may include a photo-curable organic material or a heat-curable organic material.

According to an embodiment of the present inventive concept, a protective glass substrate may be further disposed on the protective layer OC. An adhesive layer may be disposed between the protective layer OC and the glass substrate. In an embodiment of the present inventive concept, the protective layer OC may include an inorganic material.

FIG. 2B is a cross-sectional view of the display panel DP according to an embodiment of the present inventive concept. Hereinafter, in describing the display panel DP according to an embodiment with reference to FIG. 2B, the same reference numerals are given to the components described above with reference to FIG. 2A, and detailed descriptions of identical or similar elements may be omitted for convenience of explanation,

Referring to FIG. 2B, a first encapsulation layer TFE1-1 may be disposed on the second electrode CE. The first encapsulation layer TFE1-1 may include at least one inorganic layer. In an embodiment, the first encapsulation layer TFE1-1 includes a first inorganic layer IOL1-1 and a second inorganic layer IOL2-1 disposed on the first inorganic layer IOL1-1, The second inorganic layer IOL2-1 may be directly disposed on the first inorganic layer IOL1-1 (e.g., in the third direction DR3). For example, a bottom surface of the second inorganic layer IOL2-1 may be in direct contact with a top surface of the first inorganic layer IOL1-1.

The first inorganic layer IOL1-1 may be disposed on the second electrode CE. The first inorganic layer IOL1-1 may cover the first stepped portion CE-SP provided on the top surface CE-UF of the second electrode CE. The top surface IOL1-1-UF of the first inorganic layer IOL1-1 may include at least one second stepped portion IOL1-1-SP corresponding to the first stepped portion CE-SP. The second stepped portion IOL1-1-SP may overlap the emission area PXA and may not overlap the non-emission area NPXA. The second stepped portion IOU-1-SP may be provided by the first opening OP1 defined in the pixel defining layer PDL in the same manner as the first stepped portion CE-SP. As a portion of the light emitting element OLED is disposed in the first opening OP1, the second stepped portion IOL1-1-SP may be positioned on the top surface IOL1-1-UF of the first inorganic layer IOL1-1.

The second stepped portion IOL 1-1-SP of the first inorganic layer IOL1-1 may have a second height difference h2, The second height difference h2 may be defined as a height difference (e.g., length in the third direction DR3) between the top surface IOL1-1-UF of the first inorganic layer IOL1-1 at a portion overlapping the pixel defining layer PDL (e.g., an uppermost surface of the pixel defining layer PDL) and the second stepped portion IOL1-1-SP disposed to overlap the first opening OP1. The second stepped portion IOL1-1-SP may be the lowermost surface of the first inorganic layer IOL1-1 overlapping the first opening (e.g., in the third direction DR3). The second stepped portion IOL1-1-SP may have the same height difference for each of the respective emission areas PXA. For example, all of the second stepped portions IOL1-1-SP of the first inorganic layer IOL1-1 overlapping the first emission area PXA-R (see FIG. 1C), the second emission area PXA-G (see FIG. 1C), and the third emission area PXA-B (see FIG. 1C) may have the second height difference h2. However, embodiments of the present inventive concept are not necessarily limited thereto, and the height differences of the second stepped portions IOL1-1-SP may be different for the respective emission areas PXA. For example, the second stepped portions IOL1-1-SP of the first inorganic layer IOL1-1 overlapping the first emission areas PXA-R (see FIG. 1C), the second emission areas PXA-G (see FIG. 1C), and the third emission areas PXA-B (see FIG. 1C) may have height differences different from each other.

The second inorganic layer IOL2-1 may be disposed on the first inorganic layer IOL1-1. The second inorganic layer IOL2-1 may cover the second stepped portion IOL1-1-SP of the first inorganic layer IOL1-1. For example, the height difference of the second stepped portion IOL1-1-SP of the first inorganic layer IOL1-1 may be removed and planarized by the second inorganic layer IOL2-1. As the second inorganic layer IOL2-1 covers the second stepped portion IOL1-1-SP of the first inorganic layer 101-1-1, at least one stepped portion corresponding to the second stepped portion IOL1-1-SP may be defined on the bottom surface of the second inorganic layer IOL2-1.

In an embodiment, the second inorganic layer IOL2-1 may be planarized through the polishing process. As the second inorganic layer IOL2-1 is planarized through the polishing process, surface roughness of the top surface IOL2-1-UF of the second inorganic layer IOL2-1 may be reduced, and particles may be removed to increase the barrier properties of the second inorganic layer IOL2-1 against moisture and oxygen. In addition, the stepped portion provided on the first inorganic layer IOL1-1 may be removed so that the thin film is planarized, and even if an unevenness due to the particles or the like exists on the top surface IOU-1-UF of the first inorganic layer IOL1-1, the unevenness may be covered to be planarized.

In an embodiment, the top surface IOL2-1-UF of the second inorganic layer IOL2-1 disposed in at least the display area DA may be a flat surface. The top surface IOL2-1-UF of the second inorganic layer IOL2-1 disposed in the emission area PXA and the non-emission area NPXA of the display area DA may be a flat surface. A height from the bottom surface of the first electrode AE to the top surface IOL2-1-UF of the second inorganic layer IOL2-1 on the emission area PXA may be the same as that from the bottom surface of the pixel defining layer PDL to the top surface IOL2-1-UF of the second inorganic layer IOL2-1 on the non-emission area NPXA. Thus, the top surface IOL2-1-UF of the second inorganic layer IOL2-1 overlapping the second stepped portion IOL1-1-SP on the emission area PXA may be flat.

The surface roughness of the top surface IOL2-1-UF of the second inorganic layer IOL2-1 may be different from that of the top surface IOL1-1-UF of the first inorganic layer IOL1-1. As the top surface IOL2-1-UF of the second inorganic layer IOL2-1 is planarized through the polishing process, the surface roughness of the top surface IOL2-1-UF of the second inorganic layer IOL2-1 may be less than that of the top surface IOL1-1-UF of the inorganic layer IOL1-1. In an embodiment, the surface roughness of the second inorganic layer IOL2-1 that has undergone the polishing process may be in a range of about 0 nm to about 2 nm.

In an embodiment, the first encapsulation layer TFE1-1 may further include at least one inorganic layer disposed on the second inorganic layer IOL2-1. For example, the first encapsulation layer TFE1-1 may further include a third inorganic layer disposed on the second inorganic layer IOL2-1.

FIG. 2C is a cross-sectional view of the display panel DP according to an embodiment of the present inventive concept. Hereinafter, in describing the display panel DP according to an embodiment with reference to FIG. 2C, the same reference numerals are given to the components described above with reference to FIG. 2A, and detailed descriptions of identical or similar elements may be omitted for convenience of explanation.

Referring to FIG. 2C, in the display panel DP according to an embodiment, the first encapsulation layer TFE1-2 may further include an organic layer OL in contrast to the display panel DP illustrated in FIG. 2A. A first encapsulation layer TFE1-2 sealing the light emitting element OLED may be disposed on the second electrode CE. The first encapsulation layer TFE1-2 may include at least one inorganic layer and at least one organic layer. For example, in an embodiment, the first encapsulation layer TFE1-2 may include two inorganic layers and an organic layer disposed between the two inorganic layers.

The display panel DP according to an embodiment may further include an organic layer OL disposed between the first inorganic layer IOL1-2 and the second inorganic layer IOL2-2 (e.g., in the third direction DR3). The first inorganic layer IOL1-2 may be disposed on the second electrode CE. The first inorganic layer IOL1-2 may cover the first stepped portion CE-SP of the second electrode CE. For example, a height difference of the first stepped portion CE-SP provided on the top surface CE-UF of the second electrode CE may be removed and planarized by the first inorganic layer IOL1-2. As the first inorganic layer IOL1-2 covers the first stepped portion CE-SP, at least one stepped portion corresponding to the first stepped. portion CE-SP may be defined on the bottom surface of the first inorganic layer IOL1-2.

In an embodiment, the first inorganic layer IOL1-2 may be planarized through the polishing process. For example, before the organic layer OL is disposed on the first inorganic layer IOLA-2, the top surface IOL1-2-UF of the first inorganic layer IOL1-2 may be planarized through the polishing process. As the first inorganic layer IOL1-2 is planarized through the polishing process, the stepped portion provided on the display element layer DP-OLED may be removed, and then, the thin film may be planarized. In addition, surface roughness of the top surface IOL1-2-UF of the first inorganic layer IOL1-2 may be reduced, and particles may be removed. In addition, in the display panel DP according to an embodiment of the present inventive concept, there is an advantage that the process in which the top surface IOL1-2-UF of the first inorganic layer IOL1-2 is planarized through the polishing process is performed, and thus, an organic liquid for forming the organic layer OL is uniformly disposed on the first inorganic layer IOL1-2, Thus, in the display panel DP according to an embodiment, even when the organic layer OL is formed on the first inorganic layer IOL1-2 through the inkjet process, ink agglomeration and embossing phenomena may be prevented from occurring to increase visibility of the display device.

The organic layer OL may be disposed on the first inorganic layer IOL1-2 e.g., directly thereon in the third direction DR3). For example, the organic layer OL may be disposed between the first inorganic layer IOL1-2 and the second inorganic layer IOL2-2. Thus, the barrier property may be increased by decoupling the pinholes defined in the first inorganic layer OL1-2 and the second inorganic layer IOL2-2 to delay the permeation of the moisture and oxygen.

In general, a factor determining the moisture and oxygen permeation characteristics of the first and second inorganic layers IOL1-2 and IOL2-2 may be due to the pinholes defined in the thin film. It is known that the pinholes are due to the high surface roughness of the inorganic thin film or the particles. The organic layer OL may serve to further increase the barrier property of the first encapsulation layer TFE1-2 by decoupling the pinholes defined in the first inorganic layer IOL1-2 and the second inorganic layer IOL2-2. As the organic layer OL is disposed between the first inorganic layer IOL1-2 and the second inorganic layer IOL2-2, a permeation path of the moisture and oxygen may be lengthened between the first inorganic layer IOL1-2 and the second inorganic layer IOL2-2 to further increase the barrier property of the first encapsulation layer TFE1-2.

In an embodiment in which the organic layer OL is introduced between the inorganic layers IOL1-2 and IOL2-2, the barrier property may be increased, but the light transmittance of the first encapsulation layer TFE1-2 may be reduced due to the thick organic layer OL to deteriorate the emission efficiency of the light emitting element OLED. In this embodiment, the reduction in light transmittance due to the organic layer OL may be suppressed by controlling a thickness of the organic layer OL to a predetermined thickness or less. Thus, the emission efficiency of the light emitting element OLED may be increased, and thus, the visibility of the display device may be increased.

In an embodiment, the thickness of the organic layer OL may be in a range of about 0.1 μm to about 2.0 μm, in an embodiment in which the thickness of the organic layer OL is less than about 0.1 μm, the effect of delaying the moisture permeation between the inorganic layers IOL1-2 and IOL2-2 may be reduced, and in an embodiment in which the thickness of the organic layer OL is greater than about 2.0 μm, the transmittance of light emitted from the light emitting element OLED may be reduced due to the thick thickness to deteriorate the visibility of the display device. When the thickness of the organic layer OL satisfies the above-mentioned range, an excellent moisture permeation delay effect may be expected, and the transmittance of light passing through the first encapsulation layer TFE1-2 from the light emitting element OLED may increase to increase a light extraction effect.

As the first encapsulation layer TFE1-2 further includes the organic layer OL, a thickness d1-1 of the first encapsulation layer TFE1-2 (e.g., length in the third direction DR3) may be greater than the thickness d1 of the first encapsulation layer TFE1 illustrated in an embodiment of FIG. 2A. In an embodiment, the thickness d1-1 of the first encapsulation layer TFE1-2 may be in a range of about 1.0 μm to about 5.0 μm. In an embodiment in which the thickness d1-1 of the first encapsulation layer TFE1-2 is less than about 1.0 μm, the film quality may be deteriorated, and the barrier property against moisture and oxygen may be deteriorated, and also, it may be difficult to planarize the stepped portion provided on the top surface of the light control layer CCL because the thin film is thin. In an embodiment in which the thickness d1-1 of the first encapsulation layer TFE1-2 is greater than about 5.0 μm, mechanical properties due to external stress may be deteriorated, and damage such as cracks may occur in the thin film. In an embodiment in which the thickness d1-1 of the first encapsulation layer TFE1-2 satisfies the above-described range, the barrier property may be increased due to a relatively dense film quality during the deposition process, and thus, the mechanical properties due to the external stress may be increased to increase durability and reliability of the display device.

In an embodiment of the display panel DP, the second encapsulation layer TFE2 may further include an organic layer. For example, the second encapsulation layer TFE2 may further include an encapsulation organic layer disposed between the first inorganic encapsulation layer IOL10 and the second inorganic encapsulation layer IOL20 (e,g., in the third direction DR3). Also, the above description of the organic layer OL of the first encapsulation layer TFE1-2 may be equally applied to the organic encapsulation layer of the second encapsulation layer TFE2.

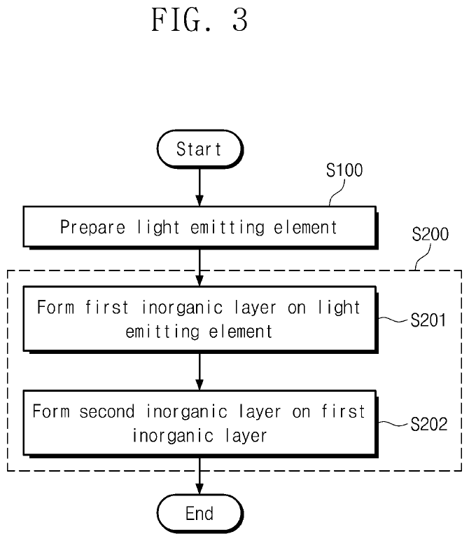

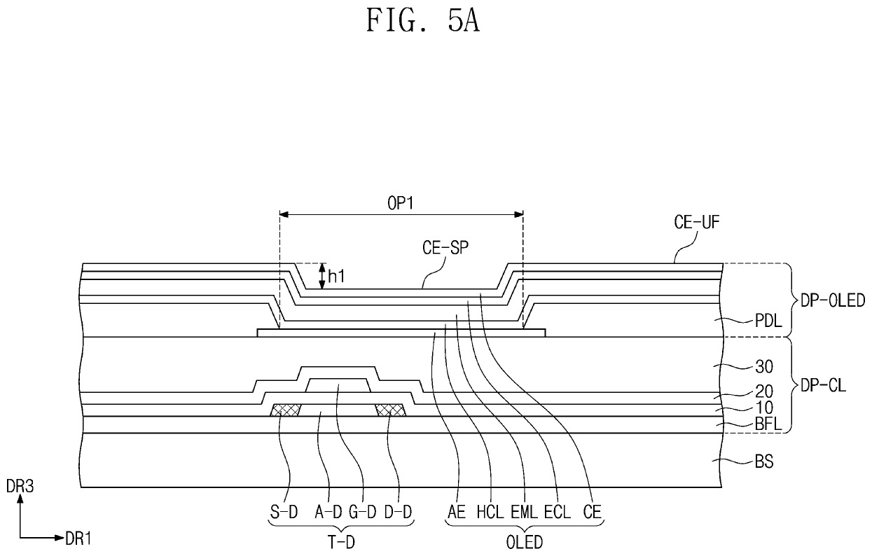

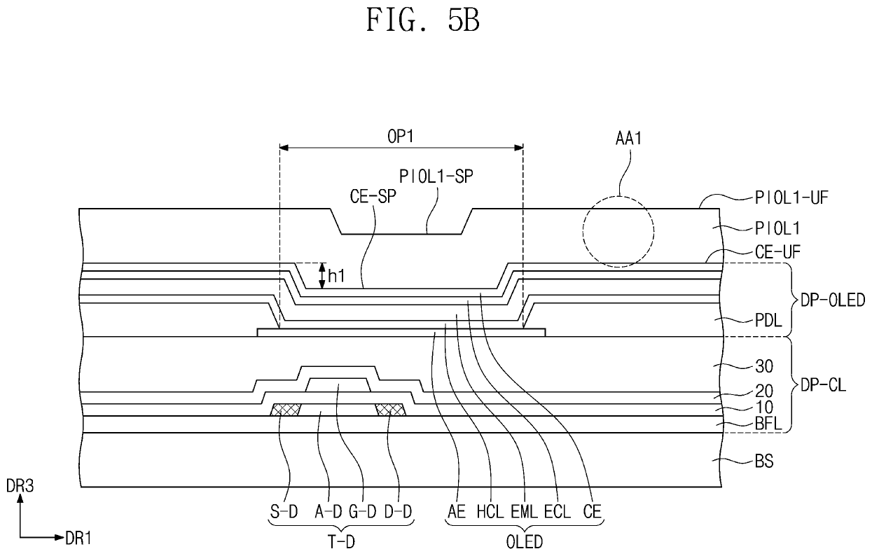

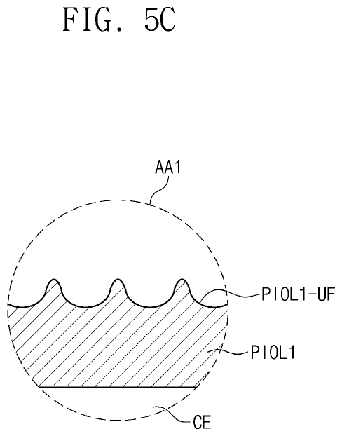

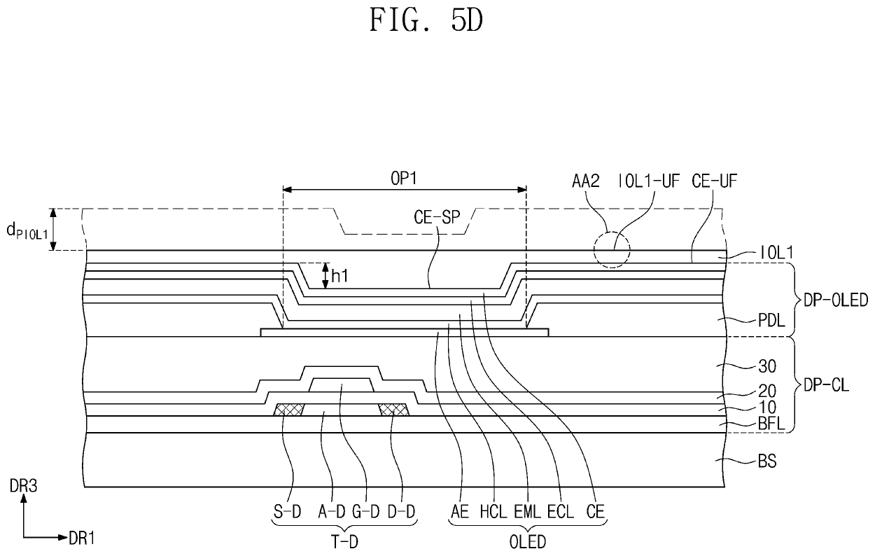

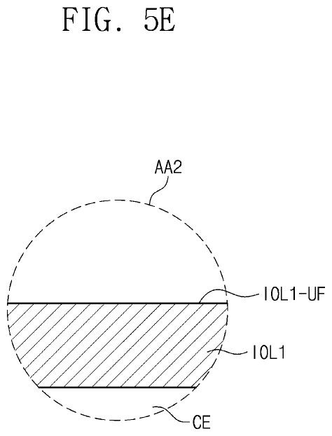

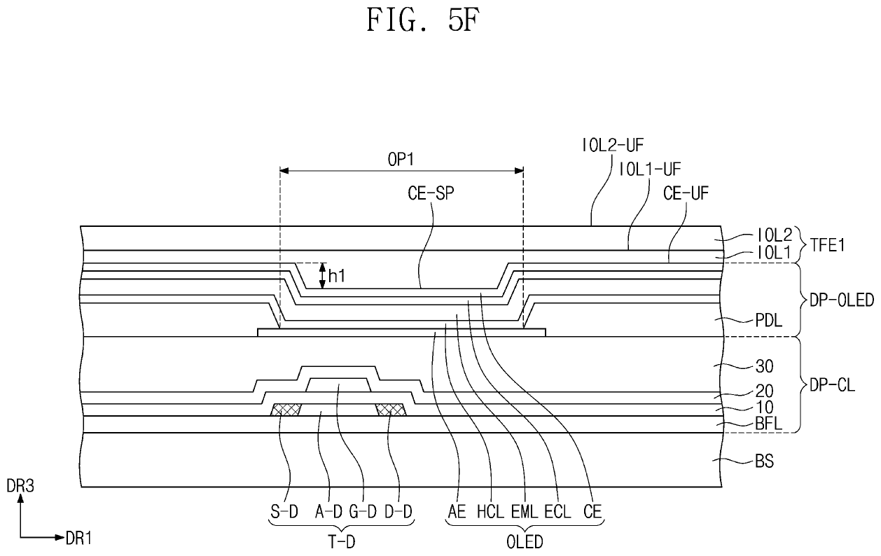

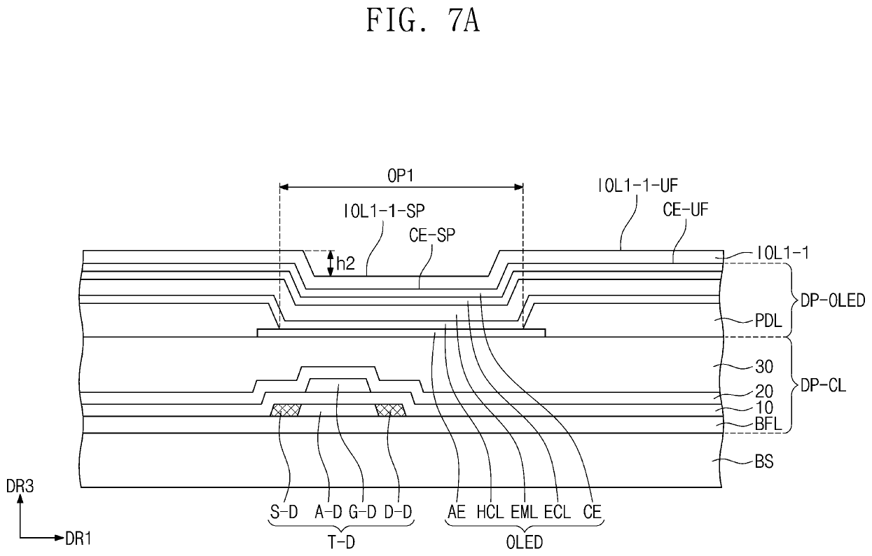

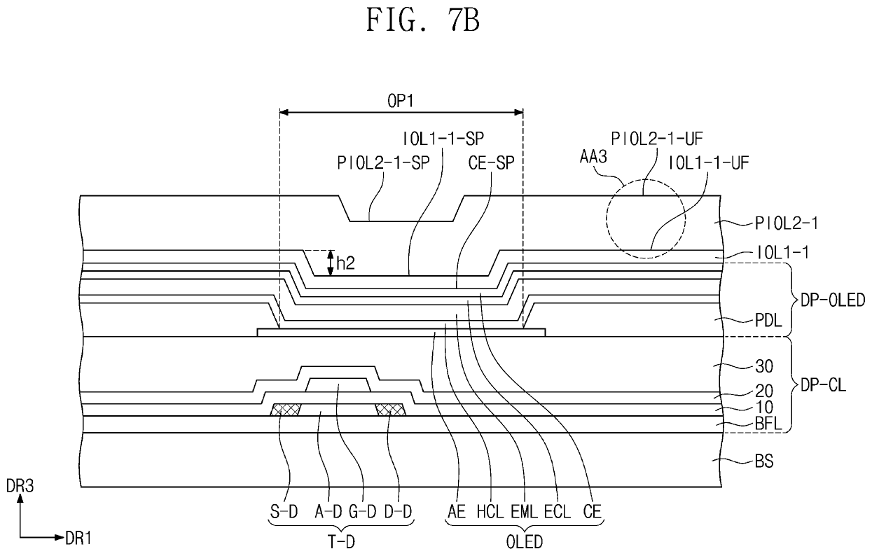

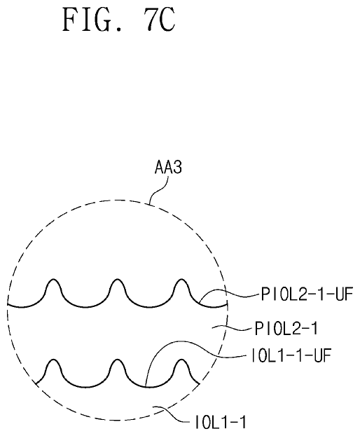

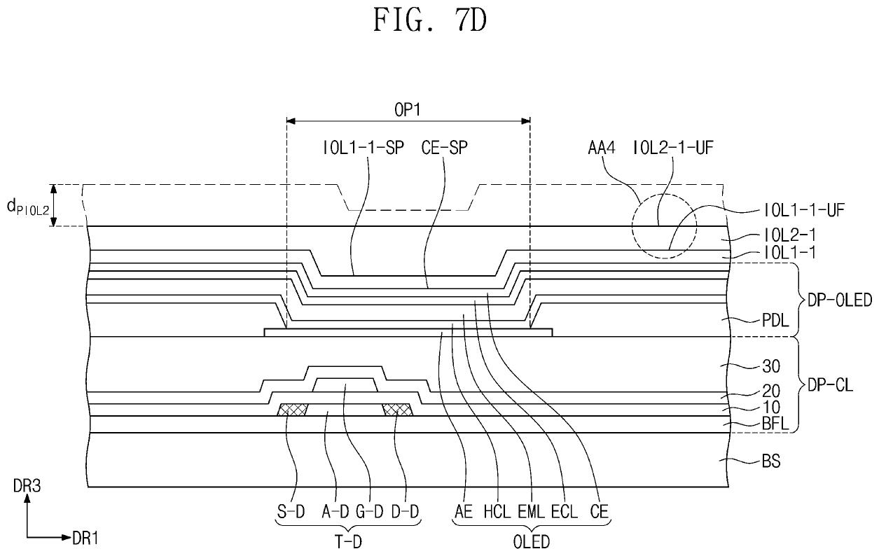

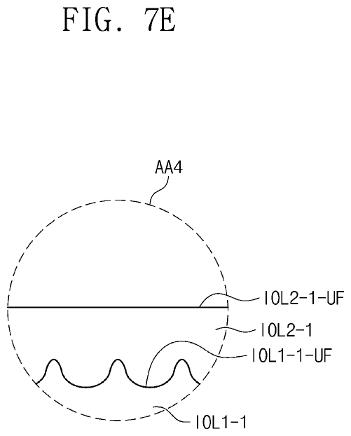

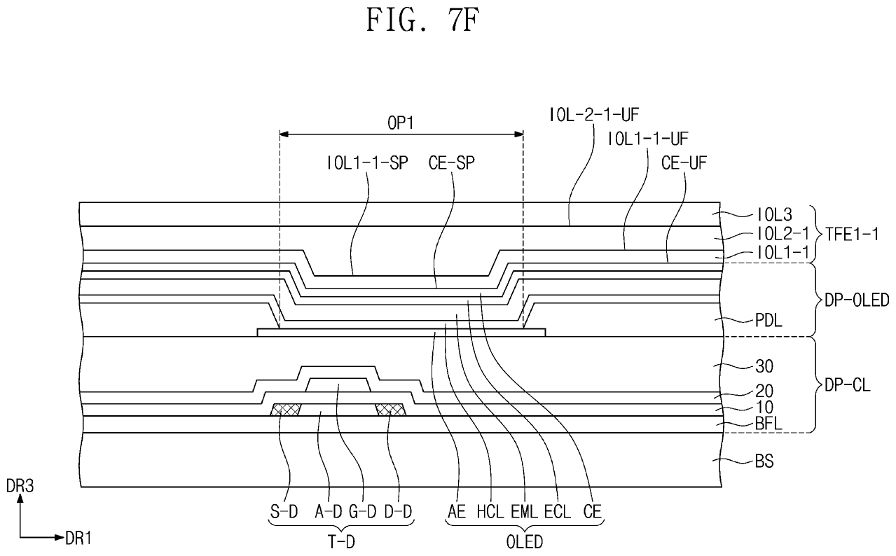

Hereinafter, a method of manufacturing a display panel will be described with. reference to embodiments of FIGS. 3, 4, 5A to 5F, 6, and 7A to 7F. In the description of the method of manufacturing the display panel according to the embodiment, the description of the display panel according to the foregoing embodiment may be applied to the display panel. Hereinafter, in description of the method for manufacturing the display panel according to embodiments of the present inventive concept, duplicated description of identical or similar elements may be omitted for convenience of explanation, and thus, differences therebetween will be mainly described. Although processes of forming a first encapsulation layer are exemplarily illustrated in FIGS. 5A to 5F and FIGS. 7A to 7F, embodiments of the present inventive concept are not necessarily limited thereto, and processes of forming a second encapsulation layer may also be performed by a manufacturing method according to embodiments of the present inventive concept.

The method for manufacturing the display panel according to an embodiment of the present inventive concept may be a method for manufacturing the display panel illustrated in embodiments of FIGS. 2A to 2C. Embodiments provide a method of manufacturing a display panel including a first encapsulation layer TFE1 applied to the display panel DP.

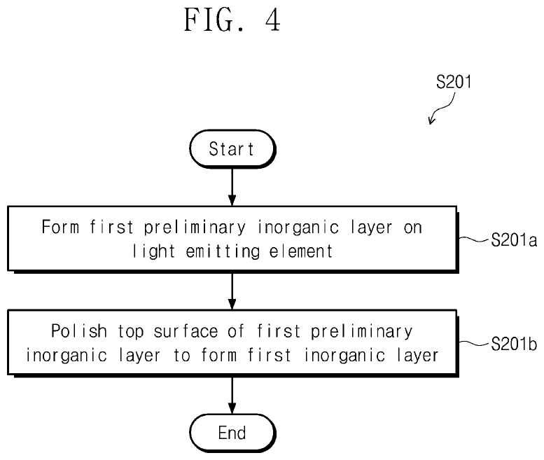

FIG. 3 is a flowchart illustrating a method for manufacturing a display device according to an embodiment of the present inventive concept. FIG. 4 is a detailed flowchart illustrating a process in block S200 of firming a first encapsulation layer according to an embodiment.

Referring to FIG. 3, a method of manufacturing a display panel according to an embodiment includes a process in block S100 of preparing a light emitting element and a process in block S200 of forming a first encapsulation layer on the light emitting element. In an embodiment, the process in block S200 of forming the first encapsulation layer on the light emitting element includes a process in block S201 of forming a first inorganic layer on the light emitting element and a process in block S202 of forming a second inorganic layer on the first inorganic layer.

FIG. 4 is a detailed flowchart illustrating a process in block S201 of forming the first inorganic layer in the process in block S200 of forming the first encapsulation layer according to an embodiment of the present inventive concept. Referring to FIG. 4, the process in block S201 of forming the first inorganic layer according to an embodiment includes a process in block S201a of forming a first preliminary inorganic layer on the light emitting element and a process in block S201b of polishing a top surface of the first preliminary inorganic layer to form the first inorganic layer.

FIGS. 5A to 5F are schematic views illustrating a process of manufacturing a display panel DP according to embodiments of the present inventive concept. FIG. 5A illustrates a process of providing a light emitting element OLED, FIG. 5B illustrates a process of providing a first preliminary inorganic layer PIOL1 on the second electrode CE, FIG. 5C is an enlarged cross-sectional view of an area AA1 of FIG. 5B, FIG. 5D illustrates a process of polishing a top surface of the first preliminary inorganic layer PIOL1 to form a first inorganic layer IOL1, FIG. 5E is an enlarged cross-sectional view of an area AA2 of FIG. 5D, and FIG. 5F illustrates a process of forming a second inorganic layer IOL2 on the first inorganic layer IOL1.

Referring to FIG. 5A, the light emitting element OLED may be provided before forming a first encapsulation layer. A top surface CE-UF of a second electrode CE of the light emitting element OLED may include at least one first stepped portion GE-SP. The first stepped portion CE-SP may be formed as a portion of the light emitting element OLED that is disposed in a first opening OP I. The first stepped portion CE-SP may have a first height difference h1. The first height difference h1 may be defined as a height difference between a top surface CE-UF of a second electrode CE at a portion overlapping a pixel defining layer PDL (e.g., an uppermost portion of the pixel defining layer PDL) and the first stepped portion CE-SP disposed to overlap the first opening OP1. The first stepped portion CE-SP may be the lowermost portion of the top surface CE-UF of the second electrode CE overlapping the first opening OP1 (e.g., in the third direction DR3).

Referring to FIG. 5B, the first preliminary inorganic layer PIOL1 may be provided on the second electrode CE (e.g., provided directly thereon in the third direction DR3). As the top surface GE-UF of the second electrode CE includes at least one first stepped portion CE-SP, a first preliminary stepped portion PIOL1-SP corresponding to the first stepped portion CE-SP may be formed on a top surface PIOL1-UF of the first preliminary inorganic layer PIOL1. For example, the top surface PIOL1-UF of the first preliminary inorganic layer PIOL1 may not be flat. In an embodiment, the first preliminary stepped portions PIOL1-SP may be removed in the process of polishing the first preliminary inorganic layer PIOL1.

A thickness of the first preliminary inorganic layer PIOL1 may be appropriately adjusted in consideration of a thickness of the first preliminary stepped portions PIOL1-SP and a desired thickness of the first inorganic layer IOL1. For example, in an embodiment the thickness of the first preliminary inorganic layer PIOL1 may be appropriately adjusted so that the first inorganic layer IOL1 is formed to a predetermined thickness on the second electrode CE, and the first preliminary stepped portion PIOL1-SP is completely removed to planarize the top surfaces IOL1-UF of the first inorganic layer IOL1. For example, the thickness of the first preliminary inorganic layer PIOL1 may be in a range of about 3.0 μm to about 5.0 μm.

In an embodiment, the thickness of the first preliminary inorganic layer PIOL1 may be at least about twice of a height difference formed on the display element layer DP-OLED. For example, the thickness of the first preliminary inorganic layer PIOL1 may be at least about twice of a first height difference h1 of the first stepped portion CE-SP formed on the top surface CE-UF of the second electrode CE. For example, the first preliminary inorganic layer PIOL1 may be provided on the second electrode CE so that the thickness of the first preliminary inorganic layer PIOL1 is at least about twice of the first height difference h1 in the third direction DR3, which is a thickness direction. However, embodiments of the present inventive concept are not necessarily limited thereto.

The first preliminary inorganic layer PIOL1 may be provided in various manners. For example, in an embodiment, the first preliminary inorganic layer PIOL1 may be provided through a method such as chemical vapor deposition (CVD), plasma enhanced chemical vapor deposition (PECVD), sputter, atomic layer deposition (ALD), or thermal evaporation.

Referring to FIG. 5C, a fine unevenness may be formed on the top surface PIOL1-UF of the first preliminary inorganic layer PIOL1. When the first preliminary inorganic layer PIOL1 is formed, the unevenness may be formed on the top surface PIOL1-UF of the first preliminary inorganic layer PIOL1 by particles or the like, which exist on the surface. The unevenness may be removed through a polishing process.

Referring to FIGS. 5B and 5D, a process of polishing the top surface PIOL1-UF of the first preliminary inorganic layer PIOL1 may be performed. In FIG. 5D, a portion removed by polishing the top surface PIOL1-UF of the first preliminary inorganic layer PIOL1 is indicated by a dotted line. The first inorganic layer IOL1 may be formed by polishing the top surface PIOL1-UF of the first preliminary inorganic layer PIOL1. In the polishing process, a height difference of a first preliminary stepped portion PIOL1-SP formed on the top surface PIOL1-UF of the first preliminary inorganic layer PEOL1 may be removed and planarized.

The process of polishing the top surface PIOL1-UF of the first preliminary inorganic layer PIOL1 may be performed in various manners. In an embodiment, the process of polishing the top surface PIOL1-UF of the first preliminary inorganic layer PIOL1 may be performed through a chemical mechanical polishing process. However, embodiments of the present inventive concept are not necessarily limited thereto.

Referring to FIGS. 5B to 5E, in the polishing process, the first preliminary inorganic layer PIOL1 may be removed to a thickness that is less than or equal to about 3.0 μm or less in the third direction DR3, which is the thickness direction. That is, a thickness d_{PIOL1} by which the first preliminary inorganic layer PIOL1 is removed in the polishing process may be less than or equal to about 3μm. In an embodiment in which the first preliminary inorganic layer PIOL1 is removed to be greater than about 3.0 μm., a total amount of the removed first preliminary inorganic layer PIOL1 may increase to decrease the manufacturing efficiency of the display panel DP, and thus, the thickness of the finally formed first inorganic layer IOL1 may be reduced to deteriorate a barrier property against moisture and oxygen.

The top surfaces IOL1-UF of the first inorganic layer that have undergone the polishing process may be flat. Also, the unevenness formed on the top surface PIOL1-UF of the first preliminary inorganic layer PIOL1 may be removed through the polishing process. For example, since defects such as particles existing on the top surface PIOL1-UI of the first preliminary inorganic layer are removed by the polishing process, moisture permeability through a thin film may be reduced.

In an embodiment, surface roughness of the top surface IOL1-UF of the first inorganic layer IOL1 may be less than that of the top surface PIOL1-UF of the first preliminary inorganic layer PIOL1. In an embodiment, the surface roughness of the top surface IOL-UF of the first inorganic layer IOL1 planarized through the polishing process may be in a range of about 0 nm to about 2 nm.

Referring to FIG. 5F, a second inorganic layer IOL2 may be provided on the first inorganic layer IOL1. As the top surfaces IOL1-UF of the first inorganic layer IOL1 are planarized through the polishing process, the second inorganic layer IOL2 may be uniformly deposited on the first inorganic layer IOL1. Thus, a film quality of the first encapsulation layer TFE1 may be increased. In an embodiment, the second inorganic layer IOL2 may also be planarized through the polishing process in the same manner as the first inorganic layer IOL1. For example, processes of forming a second preliminary inorganic layer on the first inorganic layer IOL1 and polishing a top surface of the second preliminary inorganic layer may be performed.

In an embodiment, the organic layer OL (see FIG. 2C) may be formed first on the first inorganic layer IOL1 (e.g., directly thereon in the third direction DR3) before the process of forming the second inorganic layer IOL2. The organic layer OL (see FIG. 2C) may be formed on the first inorganic layer IOL1, and then the second inorganic layer IOL2 may be formed on (e.g., formed directly thereon in the third direction DR3) the organic layer OL (FIG. 2C). Thus, as illustrated in FIG. 2C, the organic layer OL (see FIG. 2C) may be disposed between the first inorganic layer IOL1 and the second inorganic layer IOL2 (e.g., directly therebetween in the third direction DR3).

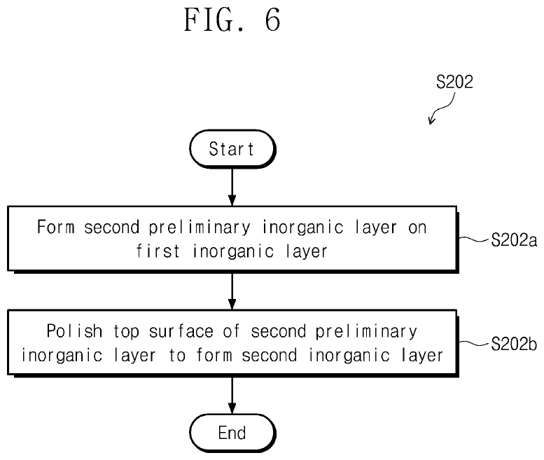

FIG. 6 is a detailed flowchart illustrating a process in block S202 of forming the second inorganic layer in the process in block S200 of forming the first encapsulation layer according to an embodiment of the present inventive concept. FIGS. 7A to 7F are schematic views illustrating a process of manufacturing the display panel DP according to embodiments of the present inventive concept. FIG. 7A illustrates a process of providing a first inorganic layer IOL1-1 on the light emitting element OLED, FIG. 7B illustrates a process of providing a second preliminary inorganic layer PIOL2-1 on the first inorganic layer IOL1-1, FIG. 7C is an enlarged cross-sectional view of an area AA3 of FIG. 7B, FIG. 7D illustrates a process of polishing a top surface PIOL2-1-UF of the second preliminary inorganic layer PIOL2-1 to form a second inorganic layer IOL2-1, FIG. 7E is an enlarged cross-sectional view of an area AA4 of FIG. 7D, and FIG. 7F illustrates a process of forming a third inorganic layer IOL3 on the second inorganic layer IOL2-1.

Hereinafter, a method of forming the first encapsulation layer TFE1 according to embodiments of the present inventive concept will be described in detail with reference to FIGS. 6 and 7A to 7F. The same content as that described with reference to FIGS. 4 and 5A to 5F will not be described again, but will be mainly described with respect to differences and a detailed description of identical or similar elements may be omitted for convenience of explanation.

A process (S200, see FIG. 3) of forming the first encapsulation layer illustrated in FIGS. 6 and 7A to 7F is different from the process (S200, see FIG. 3) of forming the first encapsulation layer, which is described with reference to FIGS. 4 and 5A to 5F in that the second inorganic layer is planarized through the polishing process. The polishing process may be performed in the process of forming the second inorganic layer instead of the first inorganic layer. For example, the process in block S202 of forming the second inorganic layer in the process (S200, see FIG. 3) of forming the first encapsulation layer according to an embodiment may include a process in block S2O2a of forming the second preliminary inorganic layer on the first inorganic layer and a process in block S202b of polishing a top surface of the second preliminary inorganic layer to form the second inorganic layer.

Referring to FIG. 7A, the first inorganic layer IOL1-1 may be provided on the second electrode CE of the light emitting element OLED. As the top surface CE-UF of the second electrode CE includes at least one first stepped portion CE-SP, a second stepped portion IOL1-1-SP corresponding to the first stepped portion CE-SP may be formed on a top surface IOL1-1-UF of the first inorganic layer IOL1-1. For example, the top suffice IOL1-1-UF of the first inorganic layer IOL1-1 may not be flat. The second stepped portion IOL1-1-SP may have a second height difference h2. The second height difference h2 may be defined as a height difference (e.g., length in the third direction DR3) between the top surface IOL1-1-UF of the first inorganic layer IOL1-1 (e.g., a surface of the first inorganic layer IOL1-1 overlapping an uppermost surface of the pixel defining layer PDL) and the second stepped portion IOL1-1-SP (e.g., a lowermost surface of the first inorganic layer IOL1-1 overlapping the at least one first stepped portion CE-SP in the third direction DR3).

Referring to FIG. 7B, a second preliminary inorganic layer PIOL2-1 may be provided on the first inorganic layer IOL1-1 (e.g., provided directly thereon in the third direction DR3). As the top surface IOL1-1-UF of the first inorganic layer IOL1-1 includes at least one second stepped portion IOL1-1-SP, a second preliminary stepped portion PIOL2-1-SP corresponding to the second stepped portion IOL1-1-SP may be foamed on a top surface PIOL2-1-UF of the second preliminary inorganic layer PIOL2-1. For example, the top surface PIOL2-1-UF of the second preliminary inorganic layer PIOL2-1 may not be flat. In this embodiment, the second preliminary stepped portion PIOL2-1-SP may be removed in the process of polishing the top surface PIOL2-1-UF of the second preliminary inorganic layer PIOL2-1.

A thickness of the second preliminary inorganic layer PIOL2-1 may be appropriately adjusted in consideration of a thickness of the second preliminary stepped portion PIOL2-1-SP and a desired thickness of the second inorganic layer IOL2-1. For example, the thickness of the second preliminary inorganic layer PIOL2-1 may be appropriately adjusted so that the second inorganic layer IOL2-1 is formed to a predetermined thickness on the first inorganic layer IOL1-1, and the second preliminary stepped portion PIOL2-1-SP is completely removed to planarize the top surfaces IOL2-1-UF of the second inorganic layer IOL2-1.

In an embodiment, the thickness of the second preliminary inorganic layer PIOL2-1 may be at least about twice of a height difference formed on the first inorganic layer IOL1-1. For example, the thickness of the second preliminary inorganic layer PIOL2-1 may be at least about twice of a second height difference h2 of the second stepped portion IOL1-1-SP formed on the top surface IOL1-1-UP of the first inorganic layer IOL1-1. For example, the second preliminary inorganic layer PIOL2-1 may be provided on the first inorganic layer IOL1-1 so that the thickness of the second preliminary inorganic layer PIOL2-I is at least about twice of the second height difference h2 in the third direction DR3, which is a thickness direction. For example, in an embodiment, the thickness of the second preliminary inorganic layer PIOL2-1 may be in a range of about 3.0 μm to about 5.0 μm. However, embodiments of the present inventive concept are not necessarily limited thereto.

The second preliminary inorganic layer PIOL2-1 may be provided in various manners. For example, in an embodiment, the second preliminary inorganic layer PIOL2-1 may be provided through a method such as chemical vapor deposition (CVD), plasma enhanced chemical vapor deposition (PECVD), sputter, atomic layer deposition (ALD), or thermal evaporation.

In an embodiment, the process of forming the first inorganic layer IOL1-1 and the process of forming the second preliminary inorganic layer PIOL2-1 may be sequentially performed. The process of forming the first inorganic layer IOL1-1 and the process of forming the second preliminary inorganic layer PIOL2-1 may be performed in the same reactor. Thus, since a process time taken to form the first encapsulation layer is shortened, it may be advantageous in terms of efficiency of the manufacture of the display device.

Referring to FIG. 7C, each of the top surface IOL1-1-LIF of the first inorganic layer IOL1-1 and the top surface PIOL2-1-UF of the second preliminary inorganic layer PIOL2-1 has a fine unevenness. In the process of forming the first inorganic layer IOL1-1, an unevenness may be formed on the top surface IOL1-1-UF of the first inorganic layer IOL1-1 by particles or the like, which exist on a surface of the first inorganic layer IOL1-1. In addition, in the process of forming the second preliminary inorganic layer PIOL2-1, an unevenness may be formed on the top surface PIOL2-1-UF of the second preliminary inorganic layer PIOL2-1 by particles or the like, which exist on a surface of the second preliminary inorganic layer PIOL2-1. The unevenness formed on the top surface PIOL2-1-UF of the second preliminary inorganic layer PIOL2-1 may be removed through a polishing process.

Referring to embodiments of FIGS. 7B and 7D, a process of polishing the top surface PIOL2-1-UF of the second preliminary inorganic layer PIOL2-1 may be performed. In an embodiment of FIG. 7D, a portion removed by polishing the top surface PIOL2-1-UF of the second preliminary inorganic layer PIOL2-1 is indicated by a dotted line. The second inorganic layer IOL2-1 may be formed by polishing the top surface PIOL2-1-LIF of the second preliminary inorganic layer PIOL2-1. In the process of polishing the top surface PIOL2-1-UF of the second preliminary inorganic layer PIOL2-1, a height difference of the second preliminary stepped portion PIOL2-1-SP, which is illustrated in FIG. 7B, may be removed and planarized. The process of polishing the top surface PIOL2-1-LIF of the second preliminary inorganic layer PIOL2-1 may be performed in various manners. In an embodiment, the process of polishing the top surface PIOL2-1-UF of the second preliminary inorganic layer PIOL2-1 may be performed through a chemical mechanical polishing process. However, embodiments of the present inventive concept are not necessarily limited thereto.

Referring to FIGS. 7B to 7E, in the polishing process, the second preliminary inorganic layer PIOL2-1 may be removed to a thickness of less than or equal to about 3.0 μm in the third direction DR3, which is the thickness direction. For example, a thickness d_{PIOL2} by which the second preliminary inorganic layer PIOL2-1 is removed in the polishing process may be less than or equal to about 3.0 μm. In an embodiment in which the second preliminary inorganic layer PIOL2-1 is removed to be greater than about 3.0 μm, a total amount of the removed second preliminary inorganic layer PIOL2-1 may increase to decrease the manufacturing efficiency of the display panel DP, and thus, the thickness of the finally formed second inorganic layer IOL2-1 may be reduced to deteriorate a barrier property against moisture and oxygen.

The top surface IOL2-1-UF of the second inorganic layer IOL2-1 that has undergone the polishing process may be flat. Also, the unevenness formed on the top surface PIOL2-1-UF of the second preliminary inorganic layer PIOL2-1 may be removed through the polishing process. For example, since defects such as particles existing on the top surface PIOL2-1-UF of the second preliminary inorganic layer PIOL2-1 are removed by the polishing process, moisture permeability through a thin film may be reduced. In addition, as the top surface IOL2-1-UF of the second inorganic layer IOL2-1 is planarized through the polishing process, even though the unevenness exists on the top surface IOL1-1-UF of the first inorganic layer IOL1-1, the unevenness may be covered by the second inorganic layer IOL2-1 to increase the film quality of the first encapsulation layer TFE1-1.

In an embodiment, surface roughness of the top surface IOL2-1-UF of the second inorganic layer IOL2-1 may be less than that of the top surface IOL1-1-UF of the first inorganic layer IOL1-1. In an embodiment, the surface roughness of the top surface IOL2-1-UF of the second inorganic layer IOL2-1 planarized through the polishing process may be in a range of about 0 nm to about 2 nm.

Referring to FIG. 7F, in an embodiment, the process of forming the first encapsulation layer (S200, see FIG. 3) may further include a process of forming a third inorganic layer IOL3 on the second inorganic layer IOL2-1 after the process of forming the second inorganic layer IOL2-1. The third inorganic layer IOL3 may be provided on the second inorganic layer IOL2-1 (e.g., disposed directly thereon in the third direction DR3). As the top surface IOL2-1-UF of the second inorganic layer IOL2-1 is planarized through the polishing process, the third inorganic layer IOL3 may be uniformly deposited on the second inorganic layer IOL2-1. Accordingly, the film quality of the finally formed first encapsulation layer TFE1-1 may be increased to further increase the barrier property and the light transmittance property.

According to an embodiment of the present inventive concept, in the display panel including the encapsulation layer on the light emitting element, the at least one inorganic layer included in the encapsulation layer may be planarized through the polishing process to increase the emission efficiency of the light emitting element and increase the moisture permeability resistance, thereby realizing the display panel having increased emission efficiency and reliability.

It will be apparent to those skilled in the art that various modifications and variations can be made in embodiments of the present inventive concept. Thus, it is intended that the present disclosure covers the modifications and variations of the present inventive concept and are not limited to the embodiments described in the detailed description of the specification.

What is claimed is:

1. A display panel comprising an emission area and a non-emission, area adjacent to the emission area, the display panel comprising:
a light emitting element comprising a first electrode, an emission layer disposed on the first electrode, and a second electrode disposed on the emission layer;
a pixel defining layer including a first opening defined therein, the first opening exposes at least a portion of the first electrode; and
a first encapsulation layer disposed on the second electrode to overlap the light emitting element,
wherein the first encapsulation layer comprises:
a first inorganic layer disposed on the second electrode; and
a second inorganic layer disposed on the first inorganic layer,
a top surface of the second electrode overlapping the first opening comprises at least one first stepped portion, and
a bottom surface of the second inorganic layer directly contacts a top surface of the first inorganic layer, and at least one of the top surface of the first inorganic layer or a top surface of the second inorganic layer is a flat surface.

2. The display panel of claim 1, wherein the first encapsulation layer has a thickness in a range of about 1.0 μm to about 5.0 μm.

3. The display panel of claim 1, wherein:
the first inorganic layer covers the first stepped portion; and
the top surface of the first inorganic layer is a flat surface on the emission area.

4. The display panel of claim 1, wherein a first height from a bottom surface of the first electrode to the top surface of the first inorganic layer on the emission area is the same as a second height from a bottom surface of the pixel defining layer to the top surface of the first inorganic layer on the non-emission area.

5. The display panel of claim 1, wherein the top surface of the first inorganic layer comprises a second stepped portion corresponding to the first stepped portion.

6. The display panel of claim 5, wherein:
the second inorganic layer covers the second stepped portion; and
the top surface of the second inorganic layer is a flat surface on the emission area.

7. The display panel of claim 1, wherein an arithmetic mean roughness of the top surface of the first inorganic layer is greater than an arithmetic mean roughness of the top surface of the second inorganic layer.

8. The display panel of claim 1, wherein the first encapsulation layer further comprises a third inorganic layer disposed on the second inorganic layer.

9. The display panel of claim 1, further comprising:
a division partition wall disposed on the first encapsulation layer and including a second opening defined therein, the second opening corresponding to the first opening;
a light control pattern disposed inside the second opening;
a second encapsulation layer disposed on the division partition wall to overlap the light control pattern; and
a color filter disposed on the second encapsulation layer to overlap the light control pattern.

10. The display panel of claim 9, wherein the second encapsulation layer has a thickness in a range of about 1.0 μm to about 5.0 μm.

11. The display panel of claim 9, wherein the second encapsulation layer comprises:
a first encapsulation inorganic layer disposed on the division partition wall; and
a second encapsulation inorganic layer disposed on the first encapsulation inorganic layer,
wherein a bottom surface of the second encapsulation inorganic layer directly contacts a top surface of the first encapsulation inorganic layer.

12. A display panel comprising:
a light emitting element comprising a first electrode, an emission layer disposed on the first electrode, and a second electrode disposed on the emission layer;
a pixel defining layer including a first opening defined therein, the first opening exposes at least a portion of the first electrode; and
a first encapsulation layer disposed on the second electrode to overlap the light emitting element,
wherein the first encapsulation layer comprises:
a first inorganic layer disposed on the second electrode; and
a second inorganic layer disposed on the first inorganic layer,
wherein the first encapsulation layer has a thickness in a range of about 1.0 μm to about 5.0 μm.

13. The display panel of claim 12, wherein at least one of a top surface of the first inorganic layer or a top surface of the second inorganic layer is a flat surface.

14. The display panel of claim 12, wherein:
the first encapsulation layer further comprises an organic layer disposed between the first inorganic layer and the second inorganic layer; and
the organic layer has a thickness in a range of about 0.1 μm to about 2.0 μm.

15. A method for manufacturing a display panel, the method comprising:
preparing a light emitting element; and
forming a first encapsulation layer on the light emitting element,
wherein the forming of the first encapsulation layer comprises:
forming a first inorganic layer on the light emitting element; and
forming a second inorganic layer on the first inorganic layer,
wherein the forming of the first encapsulation layer includes planarizing through a polishing process at least one of a top surface of the first inorganic layer or a top surface of the second inorganic layer.

16. The method of claim 15, wherein the polishing process comprises a chemical mechanical polishing process.

17. The method of claim 15, wherein the forming of the first inorganic layer comprises:
forming a first preliminary inorganic layer on the light emitting element; and
polishing a top surface of the first preliminary inorganic layer.

18. The method of claim 17, wherein a thickness of the first preliminary inorganic layer that is removed in the polishing of the top surface of the first preliminary inorganic layer is less than or equal to about 3.0 μm.

19. The method of claim 15, wherein the forming of the second inorganic layer comprises:
forming a second preliminary inorganic layer on the first inorganic layer; and
polishing a top surface of the second preliminary inorganic layer.

20. The method of claim 15, wherein the forming of the first encapsulation layer further comprises forming a third inorganic layer on the second inorganic layer after the forming of the second inorganic layer.
